(19) United States
(12) Patent Application Publication
(10) Pub. No.: US 2012/0088189 A1
(43) Pub. Date: Apr. 12, 2012

(54) CONDUCTIVE COMPOSITION, TRANSPARENT CONDUCTIVE FILM, DISPLAY ELEMENT AND INTEGRATED SOLAR BATTERY

(75) Inventors: Nori Miyagishima, Kanagawa (JP); Yoichi Hosoya, Kanagawa (JP); Kenji Naoi, Kanagawa (JP); Ryoji Nishimura, Kanagawa (JP); Kenta Yamazaki, Kanagawa (JP); Masanori Hikita, Kanagawa (JP)

(73) Assignee: FUJIFILM Corporation, Minato-ku, Tokyo (JP)

(21) Appl. No.: 13/377,119

(22) PCT Filed: Jun. 4, 2010
(86) PCT No.: PCT/JP2010/059890

§ 371 Date: Dec. 8, 2011

(30) Foreign Application Priority Data
Jun. 9, 2009 (JP) 2009-138312

(51) Int. Cl. G03F 7/20; G03F 7/004; B82Y 99/00

(52) U.S. Cl. 430/280.1; 430/270.1; 430/325; 977/762

(57) ABSTRACT

To provide a conductive composition including: a binder, a photosensitive compound, metal nanowires, and a solvent, wherein the solvent has a solubility parameter value of 30 MPa^{1/2} or less.

### TECHNICAL FIELD

The present invention relates to a conductive composition used to produce a liquid crystal display element, an electroluminescence display element, an integrated solar battery, etc.; a transparent conductive film including the conductive composition; a display element; and an integrated solar battery.

### BACKGROUND ART

A transparent conductive film obtained by using metal nanowires produced by a polyol method has been proposed in the past (refer to PTL 1). In this proposal, two-layer coating is performed by preparing and applying a silver nanowire aqueous dispersion, then applying a conductive composition containing a photosensitive compound, an adhesion promoter, an antioxidant, a photopolymerization initiator, etc.; thereafter, patterning is performed by carrying out exposure and removal of uncured portions. In this proposal, perhaps in order to secure high conductivity by making the connection between the silver nanowires closer, only the silver nanowire dispersion liquid is applied before the conductive composition is applied. However, the patterned transparent conductive film produced in this proposal has weak solvent resistance and weak alkali resistance and presents a problem of decrease in conductivity and transparency, because the silver nanowires and the conductive composition are applied in two separate layers.

Meanwhile, it has been reported that nanowires which are several tens of micrometers in major axis length and 15 nm to 50 nm in minor axis length can be obtained by reducing a silver ammonia complex in coexistence with CTAB (cetyl trimethylammonium bromide) in aqueous solvent (refer to NPTL 1).

Hence, at present, provision of the following is hoped for: a conductive composition capable of securing both transparency and conductivity even after patterning by development; a transparent conductive film including the conductive composition, superior in solvent resistance, water resistance, alkali resistance, etc.); a display element including the transparent conductive film; and an integrated solar battery including the transparent conductive film.

### CITATION LIST

### Patent Literature

[PTL 1] US Patent Application Publication No. 2007/0074316

### Non Patent Literature

[NPL 1] J. Phys. Chem. B 2005, 109, 5497-5503

### SUMMARY OF INVENTION

### Technical Problem

The present invention provides: a conductive composition capable of securing both transparency and conductivity even after patterning by development; a transparent conductive film including the conductive composition, superior in solvent resistance, water resistance, alkali resistance, etc.; a display element including the transparent conductive film; and an integrated solar battery including the transparent conductive film.

### Solution to Problem

Means for solving the above-mentioned problems are as follows.

<1> A conductive composition including: a binder; a photo/sensitive compound; metal nanowires; and a solvent, wherein the solvent has a solubility parameter value of 30 MPa^{1/2} or less.
<2> The conductive composition according to <1>, further including a cross-linking agent.
<3> The conductive composition according to <1> or <2>, wherein the solvent has a solubility parameter value of 18 MPa^{1/2} to 28 MPa^{1/2}.
<4> The conductive composition according to any one of <1> to <3>, wherein the solvent has a solubility parameter value of 19 MPa^{1/2} to 27 MPa^{1/2}.
<5> The conductive composition according to any one of <1> to <4>, having a water content of 30% by mass or less.
<6> The conductive composition according to any one of <1> to <5>, wherein the solvent contains at least one selected from the group consisting of propylene glycol monomethyl ether acetate, ethyl lactate, isopropyl acetate and 1-methoxy-2-propanol.
<7> The conductive composition according to any one of <2> to <6>, wherein the cross-linking agent is one of an epoxy resin and an oxetane resin.
<8> The conductive composition according to any one of <1> to <7>, wherein the metal nanowires have an average minor axis length of 200 nm or less and an average major axis length of 1 μm or greater.
<9> The conductive composition according to any one of <1> to <8>, wherein the metal amount of metal nanowires which are 50 nm or less in minor axis length and 5 μm or greater in major axis length occupies 50% by mass or more of the metal amount of all metal particles contained in the conductive composition.
<10> The conductive composition according to any one of <1> to <9>, wherein the metal nanowires have a minor axis length variation coefficient of 40% or less.
<11> The conductive composition according to any one of <1> to <10>, wherein the metal nanowires have round corners as seen in cross section.
<12> The conductive composition according to any one of <1> to <11>, wherein the metal nanowires contain silver.
<13> A pattern forming method including: applying the conductive composition according to any one of <1> to <12> over a base material and drying the conductive composition so as to form a conductive layer; and exposing and developing the conductive layer.
<14> A transparent conductive film including: the conductive composition according to any one of <1> to <12>.
<15> A display element including: the transparent conductive film according to <14>.
<16> An integrated solar battery including: the transparent conductive film according to <14>.

### Advantageous Effects of Invention

According to the present invention, it is possible to solve the problems in related art and provide: a conductive composition capable of securing both transparency and conductivity even after patterning by development; a transparent conductive film including the conductive composition, superior in solvent resistance, water resistance, alkali resistance, etc.; a display element including the transparent conductive film; and an integrated solar battery including the transparent conductive film.

### BRIEF DESCRIPTION OF DRAWINGS

FIG. 1 is an explanatory drawing showing a method for measuring the sharpness of a metal nanowire.

FIG. 2A is a process drawing showing an example of a method for producing cells of a CIGS thin film solar battery.

FIG. 2B is a process drawing also showing the example of the method for producing the cells of the CIGS thin film solar battery.

FIG. 2C is a process drawing also showing the example of the method for producing the cells of the CIGS thin film solar battery.

FIG. 2D is a process drawing also showing the example of the method for producing the cells of the CIGS thin film solar battery.

FIG. 3 is a drawing showing the relationship between lattice constants and band gaps regarding semiconductors each containing a group Ib element, a group IIIb element and a group VIb element.

### DESCRIPTION OF EMBODIMENTS

The following explains a conductive composition of the present invention in detail. Although the constituent features written below will be explained, often based upon typical aspects of the present invention, the present invention is not confined to these aspects.

In the present specification, numerical ranges shown using the word “to” are ranges each having a value situated before “to” as a lower limit value and a value situated after “to” as an upper limit value.

Also in the present specification, the term “light” and the terms with the prefix “photo-” are conceived as being related to visible light, ultraviolet rays, X-rays, electron beams, etc.

Also in the present specification, the term “(meth)acrylic acid” is used to denote both acrylic acid and methacrylic acid, or either of these. Similarly, the term “(meth)acrylate” is used to denote both acrylate and methacrylate, or either of these.

### (Conductive Composition)

A conductive composition of the present invention includes a binder, a photosensitive compound, metal nanowires and a solvent. The conductive composition may also include a cross-linking agent, and may further include other component(s), if necessary.

### <Binder>

The binder may be suitably selected from alkali-soluble resins which are linear organic polymers and in which each molecule (preferably each molecule that includes an acrylic copolymer or styrene copolymer as a main chain) contains at least one group (for example, carboxyl group, phosphate group, sulfonate group, etc.) that promotes alkali solubility of the resins.

Among these, preference is given to those which are soluble in organic solvent and which make development possible with weakly alkaline aqueous solution, and greater preference is given to those which contain acid-dissociable groups and which become soluble in alkali when the acid-dissociable groups dissociate by the action of acid.

Here, the term “acid-dissociable groups” means functional groups which can dissociate in the presence of acid.

A radical polymerization method known in the art may, for example, be employed to produce the binder. At the time when an alkali-soluble resin is produced by the radical polymerization method, polymerization conditions such as temperature, pressure, the type and amount of a radical initiator and the type of a solvent can be set by persons in the art with ease, and these conditions may be experimentally determined.

The linear organic polymers are preferably polymers containing carboxylic acids in side chains.

Preferred examples of the polymers containing carboxylic acids in side chains include methacrylic acid copolymers, acrylic acid copolymers, itaconic acid copolymers, crotonic acid copolymers, maleic acid copolymers, partially esterified maleic acid copolymers, acid cellulose derivatives containing carboxylic acids in side chains, and acid anhydride-added hydroxyl group-containing polymers, as mentioned in Japanese Patent Application Laid-Open (JP-A) No. 59-44615, Japanese Patent Application Publication (JP-B) Nos. 54-34327, 58-12577 and 54-25957, and JP-A Nos. 59-53836 and 59-71048. Preferred examples thereof further include polymers containing (meth)acryloyl groups in side chains.

Among these, benzyl (meth)acrylate-(meth)acrylic acid copolymer, and multicomponent copolymers which are each composed of benzyl (meth)acrylate, (meth)acrylic acid and other monomer(s) are particularly preferable.

Further, polymers containing (meth)acryloyl groups in side chains, and multicomponent copolymers which are each composed of (meth)acrylic acid, glycidyl (meth)acrylate and other monomer(s) are useful as well. These polymers may be used with their amounts not limited.

Examples thereof also include 2-hydroxypropyl (meth)acrylate-polystyrene macromonomer-benzyl methacrylate-methacrylic acid copolymer, 2-hydroxy-3-phenoxypropyl acrylate-polymethyl methacrylate macromonomer-benzyl methacrylate-methacrylic acid copolymer, 2-hydroxyethyl methacrylate-polystyrene macromonomer-methyl methacrylate-methacrylic acid copolymer, and 2-hydroxyethyl methacrylate-polystyrene macromonomer-benzyl methacrylate-methacrylic acid copolymer, as mentioned in JP-A No. 07-140654.

Specifically, the structural unit in the alkali-soluble resin is preferably composed of (meth)acrylic acid and other monomer(s) copolymerizable with the (meth)acrylic acid.

Examples of the other monomer(s) copolymerizable with the (meth)acrylic acid include alkyl (meth)acrylates, aryl (meth)acrylates and vinyl compounds. Hydrogen atoms in alkyl groups and aryl groups contained in these may be substituted with substituents.

Examples of the alkyl (meth)acrylates and the aryl (meth)acrylates include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, dicyclopentanyl (meth)acrylate, dicyclopentenyl (meth)acrylate and dicyclopentenyloxyethyl (meth)acrylate. These may be used individually or in combination.

Examples of the vinyl compounds include styrene, α-methylstyrene, vinyltoluene, glycidyl methacrylate, acrylonitrile, vinyl acetate, N-vinylpyrrolidone, tetrahydrofurfuryl methacrylate, polystyrene macromonomers, polymethyl methacrylate macromonomers, CH₂═CR¹R² and CH₂═C(R¹)(COOR³) (where R¹ denotes a hydrogen atom or a C1-C5 alkyl group, R² denotes a C6-C10 aromatic hydrocarbon ring, and R³ denotes a C1-C8 alkyl group or a C6-C12 aralkyl group). These may be used individually or in combination.

It is preferred in term of the alkali dissolution rate and film properties that the binder have a weight average molecular weight of 1,000 to 500,000, more preferably 3,000 to 300,000, even more preferably 5,000 to 200,000.

Here, the weight average molecular weight can be calculated using a standard polystyrene calibration curve, measured by gel permeation chromatography.

The amount of the binder preferably occupies 5% by mass to 90% by mass, more preferably 10% by mass to 85% by mass, even more preferably 20% by mass to 80% by mass, of the total solid content of the conductive composition. When its amount is in this range, it is possible to achieve a favorable balance between developing properties and conductivity of the metal nanowires.

### <Photosensitive Compound>

The photosensitive compound means a compound which gives an image-forming function to the conductive composition by exposure or which causes the conductive composition to start to have this function. Specific examples thereof include (1) compounds (photoacid generators) which generate acids by exposure, (2) photosensitive quinone diazide compounds, and (3) photo radical generators. These may be used individually or in combination. Additionally, a sensitizer, etc. may also be used to adjust sensitivity.

### —(1) Photoacid Generators—

Examples of the (1) photoacid generators include photoinitiators for photocationic polymerization, photoinitiators for photoradical polymerization, photo-decolorizing/photo-discoloring agents for pigments, known compounds which generate acids upon irradiation with active light or radiant rays and which are used for microresists, etc., and mixtures of these.

The (1) photoacid generators are not particularly limited and may be suitably selected according to the intended purpose. Specific examples of the (1) photoacid generators include diazonium salts, phosphonium salts, sulfonium salts, iodonium salts, imide sulfonates, oxime sulfonates, diazodisulfones, disulfones and o-nitrobenzylsulfonate. Particularly preferable among these are imide sulfonates, oxime sulfonates and o-nitrobenzylsulfonate, which are compounds that generate sulfonic acids.

Also, it is possible to use compounds (resins) in which groups or compounds that generate acids upon irradiation with active light or radiant rays have been introduced into main chains or side chains, exemplified by the compounds mentioned in U.S. Pat. No. 3,849,137, German Patent No. 3914407, JP-A Nos. 63-26653, 55-164824, 62-69263, 63-146038, 63-163452, 62-153853 and 63-146029, and so forth.

Further, it is possible use compounds which generate acids upon irradiation with light, exemplified by the compounds mentioned in U.S. Pat. No. 3,779,778, EP Patent No. 126,712, and so forth.

### —(2) Quinone Diazide Compounds—

The (2) quinone diazide compounds are obtained, for example, by subjecting 1,2-quinone diazide sulfonyl chlorides, hydroxy compounds, amino compounds, etc. to condensation reaction in the presence of a dehydrochlorinating agent.

Examples of the 1,2-quinone diazide sulfonyl chlorides include benzoquinone 1,2-diazide-4-sulfonyl chloride, naphthoquinone-1,2-diazide-5-sulfonyl chloride and naphthoquinone-1,2-diazide-4-sulfonyl chloride. Among these, naphthoquinone-1,2-diazide-4-sulfonyl chloride is particularly preferable in terms of sensitivity.

Examples of the hydroxy compounds include hydroquinone, resorcinol, pyrogallol, bisphenol A, bis(4-hydroxyphenyl)methane, 2,2-bis(4-hydroxyphenyl)hexafluoropropane, 2,3,4-trihydroxybenzophenone, 2,3,4,4′-tetrahydroxybenzophenone, 2,2′,4,4′-tetrahydroxybenzophenone, 2,3,4,2′,3′-pentahydroxybenzophenone, 2,3,4,3′,4′,5′-hexahydroxybenzophenone, bis(2,3,4-trihydroxyphenyl)methane, bis(2,3,4-trihydroxyphenyl)propane, 4b,5,9b,10-tetrahydro-1,3,6,8-tetrahydroxy-5,10-dimethylindeno[2,1-a]indene, tris(4-hydroxyphenyl)methane, tris(4-hydroxyphenyl)ethane and 4,4′-[1-[4-[1-(4-hydroxyphenyl)-1-methylethyl]phenyl]-ethylidene]bisphenol.

Examples of the amino compounds include p-phenylenediamine, m-phenylenediamine, 4,4′-diaminodiphenyl ether, 4,4′-diaminodiphenylmethane, 4,4′-diaminodiphenylsulfone, 4,4′-diaminodiphenylsulfide, o-aminophenol, m-aminophenol, p-aminophenol, 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, bis(3-amino-4-hydroxyphenyl)hexafluoropropane and bis(4-amino-3-hydroxyphenyl)hexafluoropropane.

It is preferred that any of the 1,2-quinone diazide sulfonyl chlorides, any of the hydroxy compounds, any of the amino compounds, etc. be mixed such that the molar equivalent of hydroxyl and amino groups in total is in the range of 0.5 to 1 with respect to 1 mol of the 1,2-quinone diazide sulfonyl chloride. The proportion of the dehydrochlorinating agent to the 1,2-quinone diazide sulfonyl chloride (dehydrochlorinating agent/1,2-quinone diazide sulfonyl chloride) is preferably in the range of 1/1 to 1/0.9. The reaction temperature is preferably in the range of 0° C. to 40° C., and the reaction time is preferably in the range of 1 hour to 24 hours.

Examples of reaction solvents include dioxane, 1,3-dioxolan, acetone, methyl ethyl ketone, tetrahydrofuran, chloroform, N-methylpyrrolidone and γ-butyrolactone.

Example of the dehydrochlorinating agent include sodium carbonate, sodium hydroxide, sodium hydrogen carbonate, potassium carbonate, potassium hydroxide, trimethylamine, triethylamine, pyridine and 4-dimethylaminopyridine.

Examples of the quinone diazide compounds include compounds having the following structures.

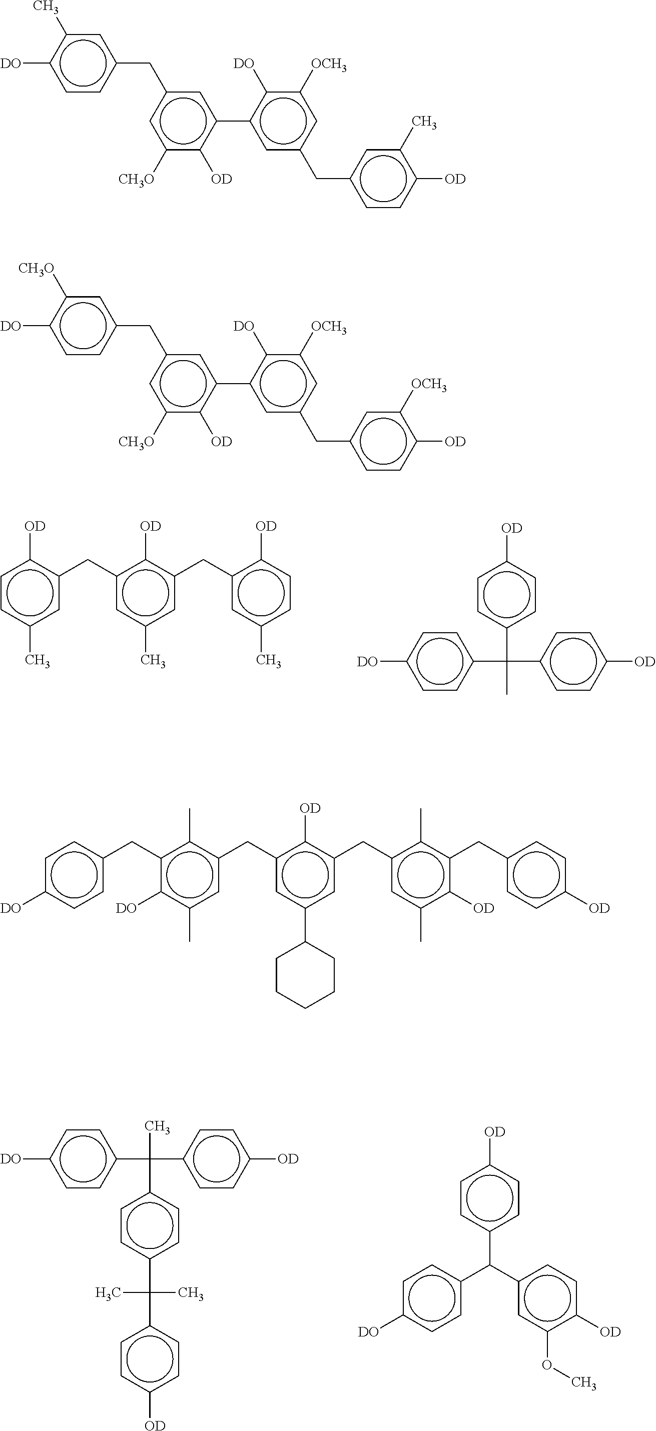

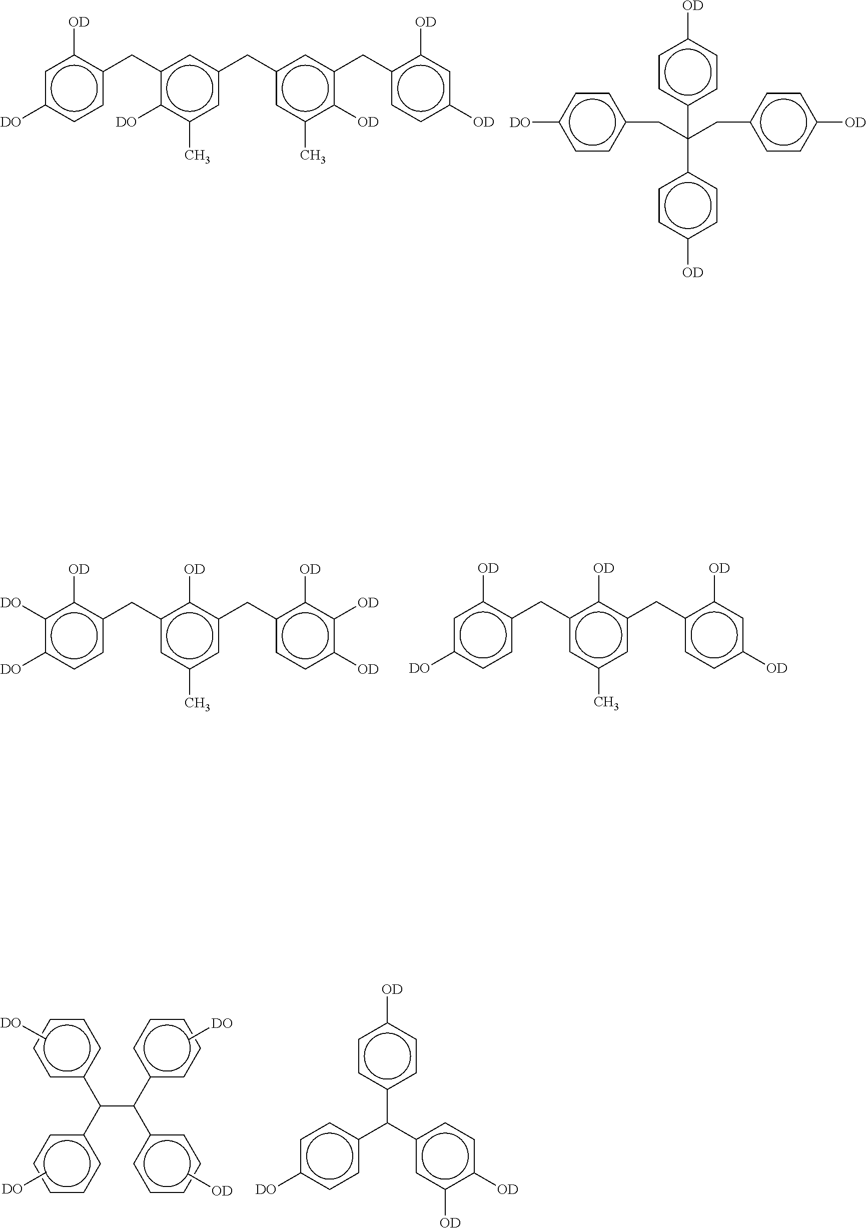

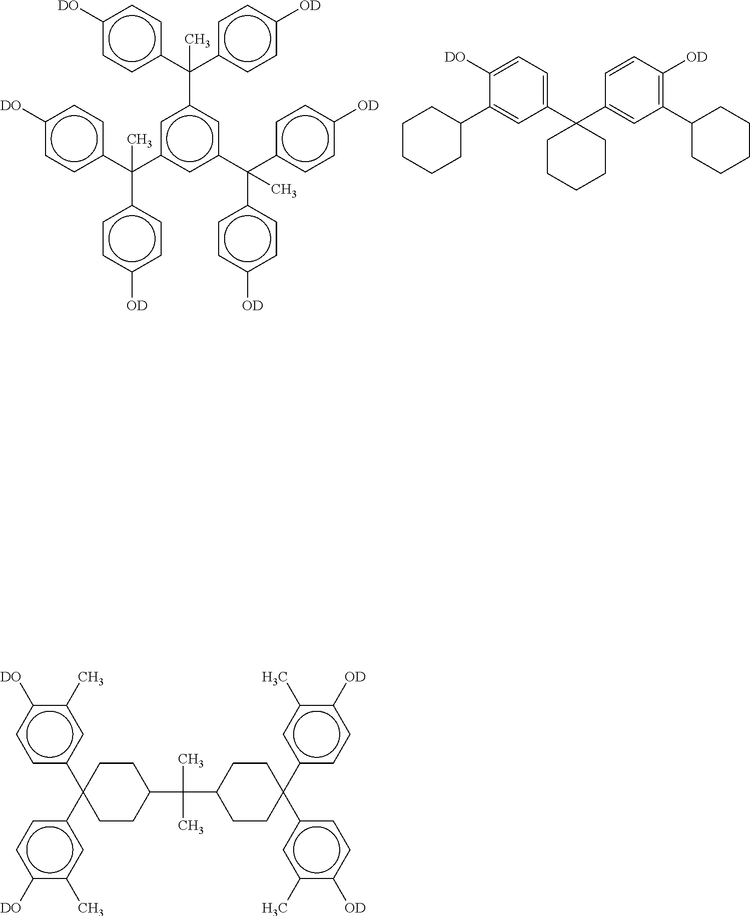

In the above formulae, D independently denotes a hydrogen atom or any of the following substituents.

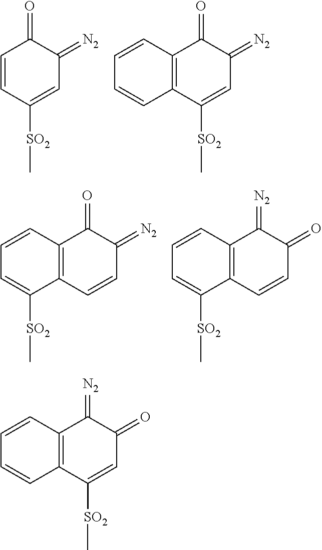

Here, it should be noted that at least one D in each compound is preferably any of the above-mentioned quinone diazide groups.

In view of an allowable range of sensitivity and the difference in dissolution rate between exposed and unexposed portions, it is preferred that the amount of any of the (1) photoacid generators and/or any of the (2) quinone diazide compounds be in the range of 1 part by mass to 100 parts by mass, more preferably 3 parts by mass to 80 parts by mass, per 100 parts by mass as the total amount of the binder.

Note that any of the (1) photoacid generators and any of the (2) quinone diazide compounds may be used in combination.

In the present invention, among the (1) photoacid generators, compounds which generate sulfonic acids are preferable, and oxime sulfonate compounds as shown below are particularly preferable in terms of sensitivity.

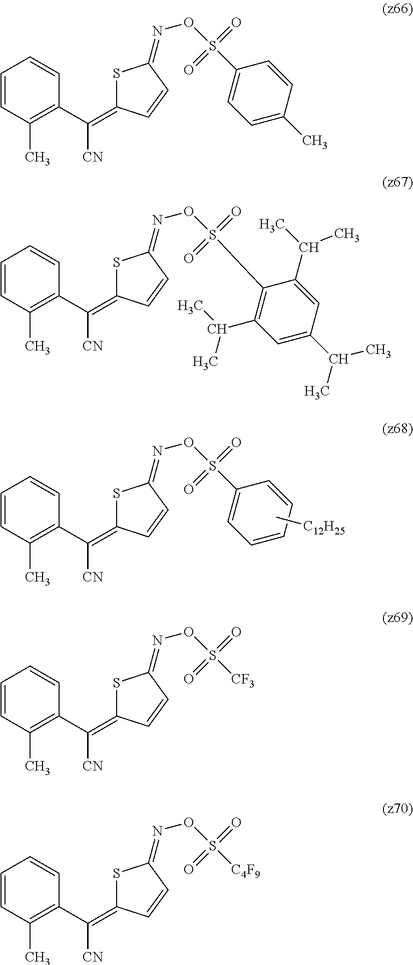

Use of a compound containing a 1,2-naphthoquinone diazide group among the (2) quinone diazide compounds can yield high sensitivity and favorable developing properties.

Among the (2) quinone diazide compounds, the following compounds where D independently denotes a hydrogen atom or 1,2-naphthoquinone diazide group are preferable in terms of sensitivity.

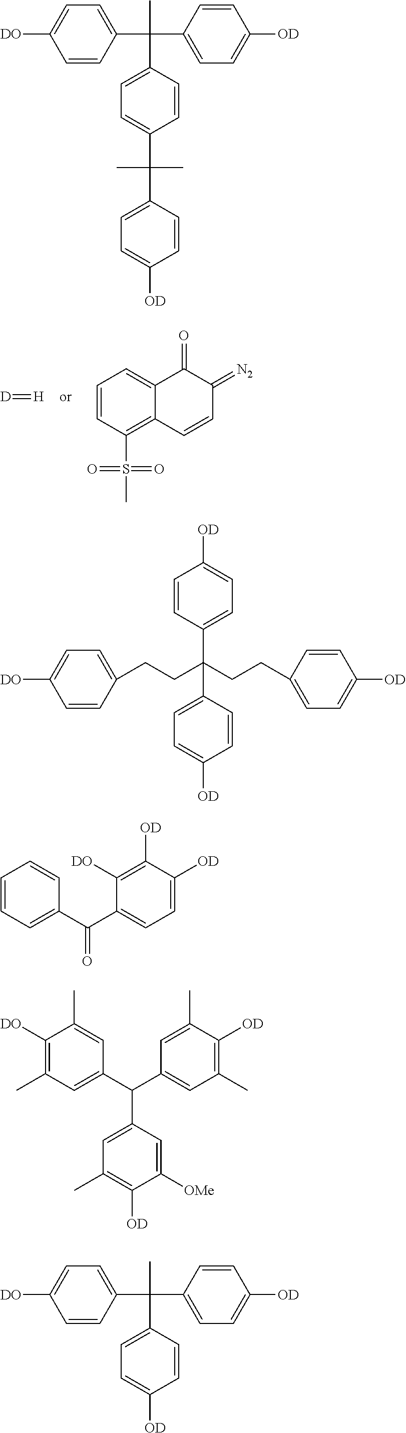

### —(3) Photo Radical Generators—

Regarding the conductive composition of the present invention, a photo radical generator having a function of inducing decomposition reaction or hydrogen abstraction reaction by absorbing light directly or being photosensitized, and thus generating polymerization active radicals may be used as the photosensitive compound. It is preferred that the photo radical generator absorb light in the wavelength range of 300 nm to 500 nm.

Regarding the photo radical generator, use of one photo radical generator alone and use of two or more photo radical generators in combination are both possible. The amount of the photo radical generator(s) preferably occupies 0.1% by mass to 50% by mass, more preferably 0.5% by mass to 30% by mass, even more preferably 1% by mass to 20% by mass, of the total solid content of the conductive composition. When the amount of the photo radical generator(s) is in this range, favorable sensitivity and pattern formability can be obtained.

The photo radical generator(s) is/are not particularly limited and may be suitably selected according to the intended purpose. Examples thereof include the compounds mentioned in JP-A No. 2008-268884. Among these, triazine compounds, acetophenone compounds, acylphosphine (oxide) compounds, oxime compounds, imidazole compounds and benzophenone compounds are particularly preferable in terms of exposure sensitivity.

Examples of the triazine compounds include 2-(4-methoxyphenyl)-4,6-bis(trichloromethyl)-s-triazine, 2-(4-methoxynaphthyl)-4,6-bis(trichloromethyl)-s-triazine, 2-(4-ethoxynaphthyl)-4,6-bis(trichloromethyl)-s-triazine, 2-(4-ethoxycarbonylnaphthyl)-4,6-bis(trichloromethyl)-s-triazine, 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bigtrichloromethyl)-s-triazine, 2-(3,4-epoxyphenyl)-4,6-bis(trichloromethyl)-s-triazine, 2-(p-chlorophenyl)-4,6-bis(trichloromethyl)-s-triazine, 2-[1-(p-methoxyphenyl)-2,4-butadienyl]-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(p-i-propyloxystyryl)-4,6-bis(trichloromethyl)-s-triazine, 2-(p-tolyl)-4,6-bis(trichloromethyl)-s-triazine, 2-(4-methoxynaphthyl)-4,6-bis(trichloromethyl)-s-triazine, 2-phenylthio-4,6-bis(trichloromethyl)-s-triazine, 2-benzylthio-4,6-bis(trichloromethyl)-s-triazine, 4-(o-bromo-p-N,N-(diethoxycarbonylamino)-phenyl)-2,6-di(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine and 2-methoxy-4,6-bis(tribromomethyl)-s-triazine. These may be used individually or in combination.

Examples of the benzophenone compounds include benzophenone, Michler's ketone, 2-methylbenzophenone, 3-methylbenzophenone, N,N-diethylaminobenzophenone, 4-methylbenzophenone, 2-chlorobenzophenone, 4-bromobenzophenone and 2-carboxybenzophenone. These may be used individually or in combination.

Examples of the acetophenone compounds include 2,2-dimethoxy-2-phenylacetophenone, 2,2-diethoxyacetophenone, 2-(dimethylamino)-2-[(4-methylphenyl)methyl]-1-[4-(4-morpholinyl)phenyl]-1-butanone, 1-hydroxycyclohexyl phenyl ketone, α-hydroxy-2-methylphenylpropanone, 1-hydroxy-1-methylethyl(p-isopropylphenyl)ketone, 1-hydroxy-1-(p-dodecylphenyl)ketone, 2-methyl-1-(4-methylthiophenyl)-2-morpholinopropan-1-one, 1,1,1-trichloromethyl-(p-butylphenyl)ketone and 2-benzyl-2-dimethylamino-1-(4-morpholinophenyl)-butanone-1. Specific suitable examples of commercially available products thereof include IRGACURE 369, IRGACURE 379 and IRGACURE 907 (manufactured by Ciba Specialty Chemicals plc.). These may be used individually or in combination.

Examples of the imidazole compounds include the compounds mentioned in JP-B No. 06-29285, U.S. Pat. Nos. 3,479,185, 4,311,783 and 4,622,286, and so forth, namely the following compounds: 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole and 2,2′-bis(o-trifluorophenyl)-4,4′,5,5′-tetraphenylbiimidazole.

Examples of the oxime compounds include the compounds mentioned in J.C.S. Perkin II (1979) 1653-1660, J.C.S. Perkin II (1979) 156-162, Journal of Photopolymer Science and Technology (1995) 202-232, and JP-A No. 2000-66385, and the compounds mentioned in JP-A Nos. 2000-80068 and 2004-534797. Specific suitable examples thereof include IRGACURE OXE-01 and IRGACURE OXE-02 (manufactured by Ciba Specialty Chemicals plc.).

Examples of the acylphosphine (oxide) compounds include IRGACURE 819, DAROCUR 4265 and DAROCUR TPO (manufactured by Ciba Specialty Chemicals plc.).

Among these, 2-(dimethylamino)-2-[(4-methylphenyl)methyl]-1-[4-(4-morpholinyl)phenyl]-1-butanone, 2-benzyl-2-dimethylamino-1-(4-morpholinophenyl)-butanone-1,2-methyl-1-(4-methylthiophenyl)-2-morpholinopropan-1-one, 2,2′-bis(2-chlorophenyl)-4,4′,5,5′-tetraphenylbiimidazole, N,N-diethylaminobenzophenone, 1,2-octanedione and 1-[4-(phenylthio)-2-(O-benzoyloxime)] are particularly preferable in term of exposure sensitivity and transparency.

In the conductive composition of the present invention, the photo radical generator(s) may be used in combination with a chain transfer agent to improve exposure sensitivity.

Examples of the chain transfer agent include N,N-dialkylaminobenzoic acid alkyl esters such as N,N-dimethylaminobenzoic acid ethyl ester; heterocyclic mercapto compounds such as 2-mercaptobenzothiazole, 2-mercaptobenzoxazole, 2-mercaptobenzoimidazole, N-phenyl mercaptobenzoimidazole and 1,3,5-tris(3-mercaptobutyloxyethyl)-1,3,5-triazine-2,4,6(1H,3H,5H)-trione; and aliphatic multifunctional mercapto compounds such as pentaerythritol tetrakis(3-mercaptopropionate), pentaerythritol tetrakis(3-mercaptobutyrate) and 1,4-bis(3-mercaptobutyryloxy)butane. These may be used individually or in combination.

The amount of the chain transfer agent preferably occupies 0.01% by mass to 15% by mass, more preferably 0.1% by mass to 10% by mass, even more preferably 0.5% by mass to 5% by mass, of the total solid content of the conductive composition.

### <Cross-Linking Agent>

The above-mentioned cross-linking agent is a compound which forms a chemical bond by means of free radicals or acid(s) and heat and cures the conductive composition. Examples thereof include melamine compounds, guanamine compounds, glycoluril compounds, urea compounds, phenolic compounds, phenolic ether compounds, epoxy compounds, oxetane compounds, thioepoxy compounds, isocyanate compounds and azide compounds, all of which are substituted with at least one group selected from methylol group, alkoxymethyl group and acyloxymethyl group; and compounds containing ethylenic unsaturated groups such as methacryloyl group and acryloyl group. Among these, epoxy compounds, oxetane compounds, and compounds containing ethylenic unsaturated groups are particularly preferable in terms of film properties, heat resistance and solvent resistance.

The compounds containing ethylenic unsaturated groups (hereinafter referred to also as “polymerizable compounds”) are addition polymerizable compounds each containing at least one ethylenic unsaturated double bond and are selected from compounds each containing one or more, preferably two or more, terminal ethylenic unsaturated bonds. For example, these compounds are in the chemical forms of monomers, prepolymers, dimers, trimers, oligomers, mixtures thereof, copolymers thereof, etc.

Examples of the polymerizable compounds include monofunctional acrylates and monofunctional methacrylates, such as polyethylene glycol mono(meth)acrylate, polypropylene glycol mono(meth)acrylate and phenoxyethyl (meth)acrylate; polyethylene glycol di(meth)acrylate, polypropylene glycol di(meth)acrylate, trimethylolethane triacrylate, trimethylolpropane triacrylate, trimethylolpropane diacrylate, neopentyl glycol di(meth)acrylate, pentaerythritol tetra(meth)acrylate, pentaerythritol tri(meth)acrylate, dipentaerythritol hexa(meth)acrylate, dipentaerythritol penta(meth)acrylate, hexanediol di(meth)acrylate, trimethylolpropane tri(acryloyloxypropyl)ether, tri(acryloyloxyethyl)isocyanurate, tri(acryloyloxyethyl)cyanurate and glycerin tri(meth)acrylate; compounds obtained by adding ethylene oxide or propylene oxide to multifunctional alcohols such as trimethylolpropane, glycerin and bisphenols to effect reaction and then subjecting the mixtures to (meth)acrylation; the urethane acrylates mentioned in JP-B Nos. 48-41708 and 50-6034, JP-A No. 51-37193, and so forth; the polyester acrylates mentioned in JP-A No. 48-64183, JP-B Nos. 49-43191 and 52-30490, and so forth; and multifunctional acrylates and multifunctional methacrylates, such as epoxy (meth)acrylates that are reaction products between epoxy resins and (meth)acrylic acid. These may be used individually or in combination.

Among these, trimethylolpropane tri(meth)acrylate, pentaerythritol tetra(meth)acrylate, dipentaerythritol hexa(meth)acrylate and dipentaerythritol penta(meth)acrylate are particularly preferable.

The epoxy compounds and the oxetane compounds are epoxy group-containing compounds and oxetanyl group-containing compounds respectively and are generally called “epoxy resins” and “oxetane resins” respectively.

Examples of the epoxy resins include bisphenol A resins, cresol novolac resins, biphenyl resins and alicyclic epoxy compounds.

Examples of the bisphenol A resins include EPOTOHTO YD-115, YD-118T, YD-127, YD-128, YD-134, YD-8125, YD-7011R, ZX-1059, YDF-8170 and YDF-170 (manufactured by Tohto Kasei Co., Ltd.); DENACOL EX-1101, EX-1102 and EX-1103 (manufactured by Nagase Chemicals Ltd.); PLACCEL GL-61, GL-62, G101 and G102 (manufactured by DAICEL CHEMICAL INDUSTRIES, LTD.); and bisphenol F resins and bisphenol S resins that are similar to the foregoing. Examples thereof also include epoxy acrylates such as EBECRYL 3700, 3701 and 600 (manufactured by Daicel-UCB Company, Ltd.).

Examples of the cresol novolac resins include EPOTOHTO YDPN-638, YDPN-701, YDPN-702, YDPN-703 and YDPN-704 (manufactured by Tohto Kasei Co., Ltd.); and DENACOL EM-125 (manufactured by Nagase Chemicals Ltd.).

Examples of the biphenyl resins include 3,5,3′,5′-tetramethyl-4,4′-diglycidylbiphenyl.

Examples of the alicyclic epoxy compounds include CELLOXIDE 2021, 2081, 2083 and 2085, EPOLEAD GT-301, GT-302, GT-401 and GT-403, and EHPE-3150 (manufactured by DAICEL CHEMICAL INDUSTRIES, LTD.); and SUN TOHTO ST-3000, ST-4000, ST-5080 and ST-5100 (manufactured by Tohto Kasei Co., Ltd.).

Examples thereof further include EPOTOHTO YH-434 and YH-434L (manufactured by Tohto Kasei Co., Ltd.) as amine epoxy resins; and glycidyl esters produced by modifying backbones of bisphenol A epoxy resins with dimer acids.

Among these epoxy resins, preference is given to novolac epoxy compounds and alicyclic epoxy compounds, particularly these having epoxy equivalents of 180 to 250. Specific examples of such materials include EPICLON N-660, N-670, N-680, N-690 and YDCN-704L (manufactured by DIC Corporation); and EHPE3150 (manufactured by DAICEL CHEMICAL INDUSTRIES, LTD.).

Examples of the oxetane resins include ARON OXETANE OXT-101, OXT-121, OXT-211, OXT-221, OXT-212, OXT-610, OX-SQ and PNOX (manufactured by TOAGOSEI CO., LTD.).

Each one of the oxetane resins may be used alone or in combination with an epoxy resin. Use thereof in combination with an epoxy resin is particularly preferable in that high reactivity can be achieved and film properties can be improved.

The amount of the cross-linking agent included in the conductive composition is preferably in the range of 1 part by mass to 250 parts by mass, more preferably 3 parts by mass to 200 parts by mass, per 100 parts by mass as the total amount of the binder.

### <Solvent>

The above-mentioned solvent helps promote dissolution or dispersion of the binder, the photosensitive compound, the cross-linking agent, etc. and enhances the fluidity of the conductive composition of the prevent invention. After the conductive composition is dried or heat-treated in a predetermined manner, most (approximately 90% or more) of the solvent is removed by evaporation or the like.

The solvent is not particularly limited and may be suitably selected according to the intended purpose; however, it is preferable to use a solvent having a boiling point of 80° C. or higher so as not to cause excessive evaporation of the solvent, which leads to precipitation of solid components of the conductive composition, at the time of the application.

The solvent has a solubility parameter value (calculated in accordance with the Okitsu method) of 30 MPa^{1/2} or less, preferably 18 MPa^{1/2} to 30 MPa^{1/2}, more preferably 18 MPa^{1/2} to 28 MPa^{1/2}, even more preferably 19 MPa^{1/2} to 27 MPa^{1/2}. When the SP value is less than 18 MPa^{1/2}, there may be degradation of solvent resistance, perhaps because components in the conductive composition have a very high affinity for the solvent. When the SP value is greater than 30 MPa^{1/2}, there may be degradation of alkali resistance, perhaps because the solubility of the metal nanowires increases too much.

The solvent may be selected from solvents whose SP values are in the above-mentioned SP value range, and the type of the solvent may be suitably selected according to the intended purpose. Examples thereof include propylene glycol monomethyl ether (23.57 MPa^{1/2}), propylene glycol monomethyl ether acetate (18.83 MPa^{1/2}), ethyl 3-ethoxypropionate (18.71 MPa^{1/2}), methyl 3-methoxypropionate (18.99 MPa^{1/2}), ethyl lactate (24.81 MPa^{1/2}), 3-methoxybutanol (22.50 MPa^{1/2}), water (43.26 MPa^{1/2}) and 1-methoxy-2-propanol. In the case where water is used as the solvent, its SP value will probably be outside the above-mentioned SP value range; accordingly, water may be used as the solvent, provided that it is used in combination with another solvent having an SP value of 30 MPa^{1/2} or less, and the overall SP value is thereby adjusted to the above-mentioned SP value range. In this case, the solvent preferably has a water content of 30% by mass or less.

To adjust the SP value, isopropyl acetate (17.22 MPa^{1/2}) or methyl lactate (26.33 MPa^{1/2}) may be used. The SP value may be adjusted by adjusting the water content of the solvent, as described above.

Also, a solvent having a high boiling point such as N-methylpyrrolidone (NMP) (22.02 MPa^{1/2}), γ-butyrolactone (GBL) (27.80 MPa^{1/2}) or propylene carbonate (29.18 MPa^{1/2}) may be used in a supplemental manner.

Among the above-mentioned compounds, at least one selected from the group consisting of propylene glycol monomethyl ether acetate, ethyl lactate, isopropyl acetate and 1-methoxy-2-propanol is/are preferably contained in the solvent and may be used in combination with water.

In another aspect of the present invention, there is provided a conductive composition including a binder, a photosensitive compound, metal nanowires, and a solvent having an SP value of 30 MPa^{1/2} or less. As this solvent having an SP value of 30 MPa^{1/2} or less, any of the above-mentioned solvents having SP values that are equal to or less than 30 MPa^{1/2} may be used.

Here, the SP value of the solvent is calculated in accordance with the Okitsu method (“Journal of the Adhesion Society of Japan”, 29(3) (1993), authored by Toshinao Okitsu). Specifically, the SP value is calculated using the following equation. Note that ΔF denotes the value mentioned in the journal.

SP value (δ)=ΣΔF(Molar attraction constants)/V(Molar volume)

In a case where a plurality of mixed solvents are used, the SP value (σ) and the hydrogen-bonding term (σh) of the SP value are calculated using the following equation.

$$σ or {σ}_{h} = \frac{{M}_{1} {V}_{1} {σ}_{1} + {M}_{2} {V}_{2} {σ}_{2} + {M}_{3} {V}_{3} {σ}_{3} + … {M}_{n} {V}_{n} {σ}_{n}}{{M}_{1} {V}_{1} + {M}_{2} {V}_{2} + {M}_{3} {V}_{3} + … {M}_{n} {V}_{n} σ}$$

In this equation, σn denotes the SP value of each solvent or the hydrogen-bonding term of the SP value of each solvent, Mn denotes the mole fraction of each solvent in the mixed solvents, Vn denotes the molar volume of each solvent, and n denotes an integer of 2 or greater which shows the number of kinds of solvents used.

Water is used when the metal nanowires are dispersed, etc.; it is necessary to adjust the composition of the solvent of the conductive composition such that the SP value of the solvent is in the SP value range prescribed in the present invention. If the conductive composition of the present invention has a high water content, the amount of residual water contained is large, and thus the in-plane resistance is high after development. Accordingly, the conductive composition preferably has a water content of 30% by mass or less, more preferably 0.1% by mass to 20% by mass, even more preferably 0.1% by mass to 10% by mass.

The water content of the conductive composition can, for example, be measured by the Karl Fischer method.

### <Metal Nanowires>

The metal nanowires are not particularly limited. For example, they may be made of a metal oxide such as ITO, zinc oxide or tin oxide, or may be metallic carbon nanotubes. They are preferably metal nanowires made of a single metal element, metal nanowires having a core-shell structure made of a plurality of metal elements, metal nanowires made of an alloy, plated metal nanowires, or the like.

In the present invention, the term “metal nanowires” means fine metal particles with an aspect ratio (average major axis length/average minor axis length) of 30 or greater.

The metal nanowires preferably have an average minor axis length (average diameter) of 200 nm or less, preferably 150 nm or less, even more preferably 100 nm or less. It should, however, be noted that when the average minor axis length is too small, there may be degradation in terms of oxidation resistance and durability; therefore, the average minor axis length is preferably 5 nm or greater. When the average minor axis length is greater than 200 nm, it may be impossible to obtain sufficient transparency, perhaps because of scattering caused by the metal nanowires.

The metal nanowires preferably have an average major axis length of 1 μm or greater, more preferably 5 μm or greater, even more preferably 10 μm or greater. It should, however, be noted that when the average major axis length is too great, aggregated matter may be produced in a production process, perhaps because the metal nanowires tangle when being produced; therefore, the average major axis length is preferably 1 mm or less, more preferably 500 μm or less. When the average major axis length is less than 1 μm, it may be impossible to obtain sufficient conductivity, perhaps because formation of a close network is difficult.

Here, the average minor axis length (average diameter) and average major axis length of the metal nanowires can, for example, be measured by using a transmission electron microscope (TEM) or an optical microscope and observing a TEM image or an optical microscope image. In the present invention, the average minor axis length (average diameter) and average major axis length of the metal nanowires are calculated by observing 300 metal nanowires with a transmission electron microscope (TEM) and averaging the minor axis lengths (diameters) and major axis lengths of these 300 nanowires.

In the present invention, the metal amount of metal nanowires which are 50 nm or less in minor axis length (diameter) and 5 μm or greater in major axis length preferably occupies 50% by mass or more, more preferably 60% by mass or more, even more preferably 75% by mass or more, of the metal amount of all metal particles contained in the conductive composition.

When the proportion of metal nanowires which are 50 nm or less in minor axis length (diameter) and 5 μm or greater in major axis length (hereinafter, this proportion will be referred to also as “appropriate wire formation rate”) in all the metal particles is less than 50% by mass, there may be a decrease in conductivity, perhaps because the amount of metal contributing to conductivity decreases, and also there may be a decrease in durability, perhaps because of concentration of voltage caused by the impossibility of forming a close wire network. Further, when particles have shapes other than the shape of the nanowires, for example spherical shapes, and thereby exhibit strong plasmon absorption, there may be degradation of transparency.

Here, the appropriate wire formation rate can be calculated as follows: in the case where the metal nanowires are silver nanowires, a silver nanowire aqueous dispersion liquid is filtered so as to separate the silver nanowires from particles which are not the silver nanowires, then the amount of silver remaining on filter paper and the amount of silver which has passed through the filter paper are measured using an ICP emission analyzer. An observation with a TEM is carried out on the metal nanowires remaining on the filter paper, in which the minor axis lengths (diameters) of 300 metal nanowires are observed and the distribution of the minor axis lengths (diameters) is examined to confirm if they are metal nanowires which are 50 nm or less in minor axis length (diameter) and 5 μm or greater in major axis length. As for the filter paper, it is preferable to use filter paper with a pore size that is ½ times or smaller than ½ times the smallest major axis of the metal nanowires and that is 5 times or greater than 5 times the greatest major axis (measured using a TEM image) of particles other than metal nanowires which are 50 nm or less in minor axis length (diameter) and 5 μm or greater in major axis length.

The metal nanowires preferably have a minor axis length (diameter) variation coefficient of 40% or less, more preferably 35% or less, even more preferably 30% or less.

When the metal nanowires have a minor axis length (diameter) variation coefficient of greater than 40%, there may be degradation of durability, perhaps because voltage is concentrated on small-diameter nanowires.

The minor axis length (diameter) variation coefficient of the metal nanowires can, for example, be worked out by measuring the minor axis lengths (diameters) of 300 metal nanowires with the use of a TEM image, and calculating the standard deviation and average value of the diameters.

The shape of the metal nanowires may be freely selected, and they may be shaped, for example, like cylinders, rectangular cuboids, columns which are polygonal in cross section, etc. When the metal nanowires are used in a situation where high transparency is required, they preferably have cylindrical shapes or shapes which are polygons having round corners instead of angles as seen in cross section.

The cross-sectional shape of each metal nanowire can be examined by applying a metal nanowire aqueous dispersion liquid over a base material, and observing a cross section of the base material coated with the dispersion liquid, using a transmission electron microscope (TEM).

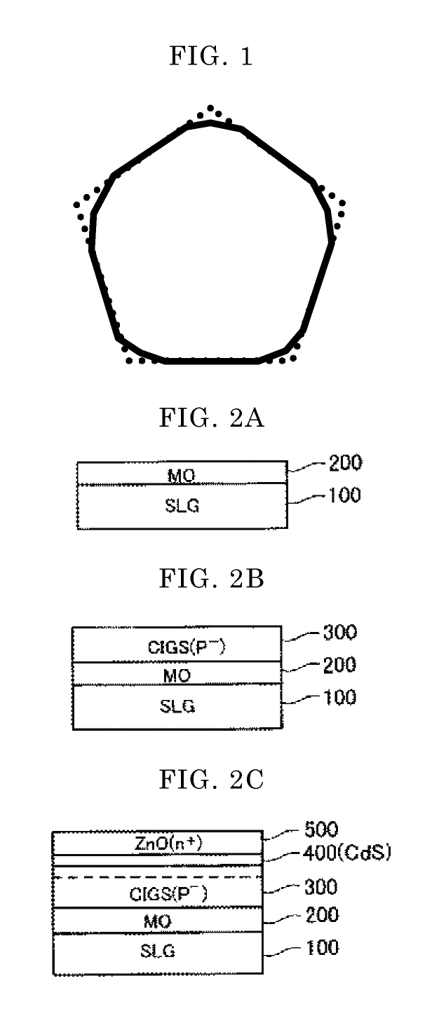

The corners of each metal nanowire in cross section mean portions in the vicinities of intersections where lines formed by extending cross-sectional sides meet lines formed by extending adjacent cross-sectional sides. The “cross-sectional sides” are defined as straight lines connecting adjacent corners among the corners. The proportion of the “cross-sectional outer circumference” to the total length of the “cross-sectional sides” is defined as “sharpness”. In the case of a cross section of a metal nanowire as shown, for example, in FIG. 1, the sharpness can be expressed as the proportion of the cross-sectional outer circumference (shown by the solid lines) to the outer circumference of the pentagon (shown by the dotted lines). When the sharpness of a cross-sectional shape is 75% or less, the cross-sectional shape is defined as a cross-sectional shape with round corners. The sharpness is preferably 60% or/less, more preferably 50% or less. When the sharpness is greater than 75%, there may be degradation of transparency (for example, yellowness remains), perhaps because of an increase in plasmon absorption caused by electrons locally present at the corners.

The metal used for the metal nanowires is not particularly limited, and the metal may be any metal. For example, the metal nanowires may be formed of a single metal, a combination of two or more metals, or an alloy. It is preferred that the metal nanowires be formed of metal(s) or metal compound(s), particularly metal(s).

The metal(s) is/are preferably at least one metal selected from the metals belonging to the fourth, fifth and sixth periods of the long-form periodic table (IUPAC 1991), more preferably at least one metal selected from the metals belonging to the 2nd to 14th groups thereof, even more preferably at least one metal selected from the metals belonging to the 2nd, 8th, 9th, 10th, 11th, 12th, 13th and 14th groups thereof. Inclusion of such metal(s) as main component(s) is particularly preferable.

Specific examples of the metal(s) include copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, and alloys of these metals. Among these, copper, silver, gold, platinum, palladium, nickel, tin, cobalt, rhodium, iridium, and alloys of these metals are preferable, particularly palladium, copper, silver, gold, platinum, tin, and alloys of these metals, more particularly silver and silver-containing alloys.

### <Method for Producing Metal Nanowires>

The above-mentioned metal nanowires are not particularly limited and may be produced in any method. However, it is preferable to produce them by reducing metal ions in a solvent dissolving a halogen compound and a dispersant as described below.

The solvent is preferably a hydrophilic solvent. Examples thereof include water; alcohols such as methanol, ethanol, propanol, isopropanol, butanol and ethylene glycol; ethers such as dioxane and tetrahydrofuran; and ketones such as acetone.

Heating may be carried out, in which case the heating temperature is preferably 250° C. or lower, more preferably in the range of 20° C. to 200° C., even more preferably 30° C. to 180° C., particularly preferably 40° C. to 170° C. If necessary, the temperature may be changed during a particle forming process. A temperature change at some point in the process can be effective in controlling nucleation, suppressing renucleation, and/or promoting selective growth, which leads to improvement in monodispersity.

When the heating temperature is higher than 250° C., there may be a decrease in transmittance in an evaluation of a coating film, perhaps because the corners of the metal nanowires in cross section are tight. Also, as the heating temperature lowers, the metal nanowires tangle more easily and there may be degradation of dispersion stability, perhaps because the probability of nucleation decreases and the metal nanowires lengthen too much. This tends to occur noticeably when the heating temperature is 20° C. or lower.

The heating is preferably carried out with the addition of a reducing agent. The reducing agent is not particularly limited and may be suitably selected from commonly used reducing agents. Examples thereof include metal salts of boron hydride such as sodium borohydride and potassium borohydride; salts of aluminum hydride such as lithium aluminum hydride, potassium aluminum hydride, cesium aluminum hydride, beryllium aluminum hydride, magnesium aluminum hydride and calcium aluminum hydride; sodium sulfite, hydrazine compounds, dextrins, hydroquinone, hydroxylamine, citric acid and salts of citric acid, succinic acid and salts of succinic acid, and ascorbic acid and salts of ascorbic acid; alkanolamines such as diethylaminoethanol, ethanolamine, propanolamine, triethanolamine and dimethylaminopropanol; aliphatic amines such as propylamine, butylamine, dipropyleneamine, ethylenediamine and triethylenepentamine; heterocyclic amines such as piperidine, pyrrolidine, N-methylpyrrolidine and morpholine; aromatic amines such as aniline, N-methylaniline, toluidine, anisidine and phenetidine; aralkyl amines such as benzylamine, xylenediamine and N-methylbenzylamine; alcohols such as methanol, ethanol and 2-propanol; ethylene glycol, glutathione, organic acids (citric acid, malic acid, tartaric acid, etc.), reducing sugars (glucose, galactose, mannose, fructose, sucrose, maltose, raffinose, stachyose, etc.) and sugar alcohols (sorbitol, etc.). Among these, reducing sugars, sugar alcohols as derivatives of reducing sugars, and ethylene glycol are particularly preferable.

The reducing agent may function also as a dispersant or a solvent depending upon the type of the reducing agent, and in this case the reducing agent can be favorably used also as the dispersant or the solvent.

As for the timing of the addition of the reducing agent, it may be added before or after the addition of the dispersant and may be added before or after the addition of the halogen compound and/or halogenated fine metal particles.

When the metal nanowires are produced, it is preferable to use the dispersant, and the halogen compound and/or the halogenated fine metal particles.

As for the timing of the addition of the dispersant and the halogen compound, they may be added before or after the addition of the reducing agent and may be added before or after the addition of the metal ions or the halogenated fine metal particles. However, to obtain nanowires which are better in monodispersity, it is preferable to add the halogen compound in two or more stages because this possibly enables control of nucleation and growth.

As to when the dispersant is added, it may be added before the preparation of particles, if necessary in the presence of a dispersion polymer, or may be added after the preparation of the particles to control the dispersed state. In the case where the dispersant is added in two or more stages, the amount of the dispersant, needs to be changed according to the length of the metal nanowires required. It is inferred that this is necessary due to the adjustment of the length of the metal nanowires by control of the amount of metal particles, which is vitally important.

Examples of the dispersant include amino group-containing compounds, thiol group-containing compounds, sulfide group-containing compounds, amino acids, derivatives of amino acids, peptide compounds, polysaccharides, natural polymers derived from polysaccharides, synthetic polymers, and polymers such as gels derived from these compounds.

Examples of the polymers (mentioned as the last item in the above-mentioned examples) include polymers with protective colloidal nature such as gelatins, polyvinyl alcohol (P-3), methylcellulose, hydroxypropylcellulose, polyalkyleneamines, partial alkyl esters of polyacrylic acid, polyvinylpyrrolidone and polyvinylpyrrolidone copolymers.

Regarding details of dispersants usable as the dispersant, the description in “Encyclopedia of Pigment” (Seishiro Ito, published by Asakura Publishing Co., Ltd. in the year 2000) may, for example, be referred to.

The shape of the metal nanowires obtained can be changed depending upon the type of the dispersant used.

The halogen compound is not particularly limited as long as it contains bromine, chlorine or iodine, and it may be suitably selected according to the intended purpose. Preferred examples thereof include alkali halides such as sodium bromide, sodium chloride, sodium iodide, potassium iodide, potassium bromide and potassium chloride; and the after-mentioned substances able to serve also as the dispersant. As for the timing of the addition of the halogen compound, it may be added before or after the addition of the dispersant and may be added before or after the addition of the reducing agent.

The halogen compound may function also as a dispersant depending upon the type of the halogen compound, and in this case the halogen compound can be favorably used also as the dispersant.

Halogenated fine silver particles may be used as an alternative to the halogen compound, or the halogen compound and halogenated fine silver particles may be used in combination.

The same substance may be used to serve as both the dispersant and the halogen compound or the halogenated fine silver particles. Examples of compounds able to serve as both the dispersant and the halogen compound include HTAB (hexadecyltrimethylammonium bromide), which contains an amino group and a bromide ion; HTAC (hexadecyltrimethylammonium chloride), which contains an amino group and a chloride ion; and dodecyltrimethylammonium bromide, dodecyltrimethylammonium chloride, stearyltrimethylammonium bromide, stearyltrimethylammonium chloride, decyltrimethylammonium bromide, decyltrimethylammonium chloride, dimethyldistearylammonium bromide, dimethyldistearylammonium chloride, dilauryldimethylammonium bromide, dilauryldimethylammonium chloride, dimethyldipalmitylammonium bromide and dimethyldipalmitylammonium chloride, each of which contains an amino group and a bromide ion or a chloride ion.

Desalination may be carried out by means of ultrafiltration, dialysis, gel filtration, decantation, centrifugation, suction filtration, etc., after the metal nanowires have been formed.

It is preferred that inclusion of inorganic ions such as alkali metal ions, alkaline earth metal ions or halide ions in the metal nanowires be prevented as much as possible. When the metal nanowires are in the form of an aqueous dispersion, its electrical conductivity is preferably 1 mS/cm or less, more preferably 0.1 mS/cm or less, even more preferably 0.05 mS/cm or less.

When the metal nanowires are in the form of an aqueous dispersion, its viscosity at 20° C. is preferably in the range of 0.5 mPa·s to 100 mPa·s, more preferably 1 mPa·s to 50 mPa·s.

The amount of the metal nanowires included in the conductive composition is preferably in the range of 1 part by mass to 200 parts by mass, more preferably 2 parts by mass to 100 parts by mass, even more preferably 3 parts by mass to 60 parts by mass, per 20 parts by mass of the binder.

When their amount is less than 1 part by mass, there may be degradation of conductivity, perhaps because contact between the metal nanowires is hindered by the binder. When their amount is greater than 200 parts by mass, the amount of the binder, is so small that there may be degradation of resolution owing to a change in developing property and there may be degradation of conductivity.

The conductive composition of the present invention preferably includes a cross-linking agent and may, if necessary, include additive(s) such as a surfactant, an antioxidant, an anti-sulfuration agent, a metal corrosion inhibitor, a viscosity adjuster, a preservative, etc., besides including the binder, the photosensitive compound, the metal nanowires and the solvent.

The metal corrosion inhibitor is not particularly limited and may be suitably selected according to the intended purpose. Suitable examples thereof include thiols and azoles.

Examples of the azoles include benzotriazole, tolyltriazole, mercaptobenzothiazole, mercaptobenzotriazole, mercaptobenzotetrazole, (2-benzothiazolylthio)acetic acid and 3-(2-benzothiazolylthio)propionic acid.

Examples of the thiols include alkanethiols and fluorinated alkanethiols. Specific examples thereof include dodecanethiol, tetradecanethiol, hexadecanethiol, octadecanethiol and fluorodecanethiol; and alkali metal salts, ammonium salts and amine salts of these thiols. The inclusion of the metal corrosion inhibitor makes it possible to exhibit an excellent rust-preventing effect. The metal corrosion inhibitor may be added, in a dissolved state in an appropriate solvent or in powder form, into a solvent dissolving the conductive composition or may be provided by producing the after-mentioned patterned transparent conductive film which includes the conductive composition and then immersing this film in a metal corrosion inhibitor bath.

### (Pattern Forming Method)

A pattern forming method of the present invention includes: applying the conductive composition of the present invention over a base material and drying the conductive composition so as to form a conductive layer; and exposing and developing the conductive layer.

The exposure varies depending upon the use, etc. and may be suitably selected. Details of the exposure will be explained in relation to the after-mentioned patterning of a transparent conductive film.

As a developing solution for use in the development after the exposure, an alkali solution is preferable. Examples of the alkali contained in the alkali solution include tetramethylammonium hydroxide, tetraethylammonium hydroxide, 2-hydroxyethyltrimethylammonium hydroxide, sodium carbonate, sodium hydrogen carbonate, potassium carbonate, potassium hydrogen carbonate, sodium hydroxide and potassium hydroxide. As the developing solution, an aqueous solution containing any of these alkalis can be suitably used.

More specifically, examples of the developing solution include aqueous solutions containing organic alkalis such as tetramethylammonium hydroxide, tetraethylammonium hydroxide and 2-hydroxyethyltrimethylammonium hydroxide, or inorganic alkalis such as sodium carbonate, sodium hydroxide and potassium hydroxide.

Any of methanol, ethanol and a surfactant may be added to the developing solution for the purpose of reducing development residues and making a patterned shape more suitable. The surfactant may be selected from anionic surfactants, cationic surfactants and nonionic surfactants. Among these, polyoxyethylene alkyl ethers, which are nonionic surfactants, are particularly preferable in that their addition yields an increase in resolution.

The method of the development is not particularly limited and may be suitably selected according to the intended purpose. Examples thereof include dip development, paddle development and shower development.

### (Transparent Conductive Film)

Since a transparent conductive film of the present invention has relatively high resolution when patterned, it can be suitably used for forming a patterned conductive film. Here, the conductive film means, for example, a film (interlayer conductive film), etc. provided to effect conduction between elements disposed in the form of layers.

The transparent conductive film is formed in the following manner.

The conductive composition of the present invention is applied over a substrate of glass, etc. by a known method such as spin coating, roll coating or slit coating. At this time, the metal nanowires may be applied over the substrate first, and then the conductive composition may be applied over the metal nanowires, which is followed by drying, to thereby form the conductive composition of the present invention; however, it is preferable to disperse the metal nanowires in a resinous coating solution and then apply the solution with the nanowires at one time to thereby form the conductive composition of the present invention.

The substrate is not particularly limited and may be suitably selected according to the intended purpose. Examples thereof include substrates of transparent glasses such as white plate glass, blue plate glass and silica-coated blue plate glass; sheets, films or substrates of synthetic resins such as polycarbonates, polyether sulfones, polyesters, acrylic resins, vinyl chloride resins, aromatic polyamide resins, polyamide-imides and polyimides; metal substrates such as aluminum plates, copper plates, nickel plates and stainless plates; ceramic plates, and semiconductor substrates including photoelectric conversion elements. If desirable, these substrates may be subjected to pretreatment(s) such as chemical treatment which uses a silane coupling agent or the like, plasma treatment, ion plating, sputtering, gas phase reaction, vacuum vapor deposition, etc.

Next, the composition-coated substrate is generally dried at 60° C. to 120° C. for 1 minute to 5 minutes on a hotplate or in an oven. The dried composition-coated substrate is then irradiated with ultraviolet rays while a mask having a desired patterned shape is placed over the composition-coated substrate. As for irradiation conditions, it is desirable that i-rays be applied at an intensity of 5 mJ/cm² to 1,000 mJ/cm².

The composition-coated substrate is subjected to development using a general developing method (such as shower development, spray development, paddle development or dip development), which is followed by adequate washing with purified water. Thereafter, the whole surface of the composition-coated substrate is irradiated again with ultraviolet rays at an intensity of 100 mJ/cm² to 1,000 mJ/cm² and finally subjected to firing at 180° C. to 250° C. for 10 minutes to 120 minutes. By doing so, a desired patterned transparent film can be obtained.

The patterned transparent conductive film thus obtained may be used as a patterned conductive film. Pores formed in the conductive film are preferably shaped like squares, rectangles, circles or ellipses as seen from immediately above. Additionally, a film which undergoes orientation treatment may be formed over the patterned conductive film. High in solvent resistance and heat resistance, the conductive film does not allow creases to form therein even when the film which undergoes the orientation treatment is formed, and thus the conductive film can maintain its high transparency.

### (Display Element)

A liquid crystal display element as a display element of the present invention is produced as follows: an element substrate obtained by providing a patterned transparent conductive film over a substrate as described above and a color filter substrate as an opposite substrate are attached to each other under kessure with their positions adjusted; thereafter, these substrates are heat-treated and combined together, then liquid crystals are injected, and subsequently an injection inlet is sealed. On this occasion, the transparent conductive film formed over the color filter is preferably formed with the above-mentioned conductive composition of the present invention.

Alternatively, a liquid crystal display element may be produced by scattering liquid crystals over the element substrate, then fitting together the substrates, and performing tight sealing in such a manner as to prevent leakage of the liquid crystals.

In this manner, the conductive film with superior transparency formed with the conductive composition of the present invention can be used in the liquid crystal display element.

It should be noted that the liquid crystals, namely liquid crystal compound(s) and liquid crystal composition(s), used in the liquid crystal display element of the present invention are not particularly limited, and any liquid crystal compound(s) and any liquid crystal composition(s) may be used.

### (Integrated Solar Battery Including Transparent Conductive Film of the Present Invention)

An integrated solar battery (hereinafter referred to also as “solar battery device”) of the present invention is not particularly limited, and any general solar battery device can be used. Examples thereof include monocrystalline silicon solar battery devices, polycrystalline silicon solar battery devices, amorphous silicon solar battery devices with single junctions or tandem structures, III-V compound semiconductor solar battery devices such as gallium arsenide (GaAs) semiconductor solar battery devices and indium phosphide (InP) semiconductor solar battery devices, II-VI compound semiconductor solar battery devices such as cadmium telluride (CdTe) semiconductor solar battery devices, compound semiconductor solar battery devices such as copper/indium/selenium (so-called CIS) semiconductor solar battery devices, copper/indium/gallium/selenium (so-called CIGS) semiconductor solar battery devices and copper/indium/gallium/selenium/sulfur (so-called CIGSS) semiconductor solar battery devices, dye-sensitized solar battery devices and organic solar battery devices. In the present invention, among these solar battery devices, preference is given to amorphous silicon solar battery devices with tandem structures, and I-III-VI compound semiconductor solar battery devices such as copper/indium/selenium (so-called CIS) semiconductor solar battery devices, copper/indium/gallium/selenium (so-called CIGS) semiconductor solar battery devices and copper/indium/gallium/selenium/sulfur (so-called CIGSS) semiconductor solar battery devices.

In the case of an amorphous silicon solar battery device with a tandem structure or the like, any of the following layers can be used as a photoelectric conversion layer: an amorphous silicon thin film, a fine crystalline silicon thin film, these thin films containing germanium, and two or more of such thin films constituting a tandem structure. These layers are formed by plasma CVD or the like.

### [Method for Producing Transparent Conductive Layer]

The transparent conductive layer used in the solar battery of the present invention can be applied to all the above-mentioned solar battery devices. The transparent conductive layer may be included in any portion of the solar battery device; however, it is preferably adjacent to the photoelectric conversion layer. The positional relationship between the transparent conductive layer and the photoelectric conversion layer is preferably as shown in the following non-limiting structures. Also, in each of the following structures, not all components constituting a solar battery device are mentioned: components are mentioned to such an extent that the positional relationship between the transparent conductive layer and the photoelectric conversion layer can be understood.

(A) Substrate-Transparent conductive layer (Product of the present invention)-Photoelectric conversion layer
(B) Substrate-Transparent conductive layer (Product of the present invention)-Photoelectric conversion layer-Transparent conductive layer (Product of the present invention)
(C) Substrate-Electrode-Photoelectric conversion layer-Transparent conductive layer (Product of the present invention)
(D) Back electrode-Photoelectric conversion layer-Transparent conductive layer (Product of the present invention)

The transparent conductive layer is formed by applying the aqueous dispersion over a substrate and drying the aqueous dispersion.

After applied, the aqueous dispersion may be annealed by heating. At this time, the heating temperature is preferably in the range of 50° C. to 300° C., more preferably 70° C. to 200° C.

The method of applying the dispersion is not particularly limited and may be suitably selected according to the intended purpose. Examples thereof include web coating, spray coating, spin coating, doctor blade coating, screen printing, gravure printing and inkjet processing. Web coating, screen printing and inkjet processing, in particular, enable flexible roll-to-roll production of the dispersion over the substrate.

Examples of the substrate include, but are not limited to, the following.

(1) Glasses such as quartz glass, alkali-free glass, crystallized transparent glass, Pyrex (registered trademark) glass and sapphire glass
(2) Acrylic resins such as polycarbonates and polymethyl methacrylate; vinyl chloride resins such as polyvinyl chloride and vinyl chloride copolymers; and thermoplastic resins such as polyarylates, polysulfones, polyethersulfones, polyimides, PET, PEN, fluorine resins, phenoxy resins, polyolefin resins, nylons, styrene resins and ABS resins
(3) Thermosetting resins such as epoxy resins

The surface of the substrate may be subjected to hydrophilizing treatment. Also, the surface of the substrate is preferably coated with a hydrophilic polymer. By doing so, the applicability and adhesion of the aqueous dispersion to the substrate improve.

The hydrophilizing treatment is not particularly limited and may be suitably selected according to the intended purpose. Examples thereof include chemical treatment, mechanical surface-roughening treatment, corona discharge treatment, flame treatment, ultraviolet treatment, glow discharge treatment, active plasma treatment and laser treatment. The surface tension of the surface is preferably made to be 30 dyne/cm or greater by any of these hydrophilizing treatments.

The hydrophilic polymer with which the surface of the substrate is coated is not particularly limited and may be suitably selected according to the intended purpose. Examples thereof include gelatins, gelatin derivatives, caseins, agars, starches, polyvinyl alcohol, polyacrylic acid copolymers, carboxymethyl cellulose, hydroxyethyl cellulose, polyvinylpyrrolidone and dextrans.

The thickness of the hydrophilic polymer layer (when dry) is preferably in the range of 0.001 μm to 100 μm, more preferably 0.01 μm to 20 μm.

The hydrophilic polymer layer is preferably increased in layer strength by the addition of a hardener. The hardener is not particularly limited and may be suitably selected according to the intended purpose. Examples thereof include aldehyde compounds such as formaldehyde and glutaraldehyde; ketone compounds such as diacetyl and cyclopentanedione; vinyl sulfone compounds such as divinyl sulfone; triazine compounds such as 2-hydroxy-4,6-dichloro-1,3,5-triazine; and the isocyanate compounds mentioned in U.S. Pat. No. 3,103,437.

The hydrophilic polymer layer can be formed by dissolving or dispersing any of the above-mentioned compounds in a solvent such as water so as to prepare a coating solution, applying the obtained coating solution over the hydrophilized substrate surface by a coating method such as spin coating, dip coating, extrusion coating, bar coating or die coating, and drying the coating solution. The drying temperature is preferably 120° C. or lower, more preferably in the range of 30° C. to 100° C., even more preferably 40° C. to 80° C.

If necessary, an underlying layer may be formed between the substrate and the hydrophilic polymer layer for the purpose of improving adhesion.

### —CIGS Solar Battery—

The following explains a CIGS solar battery in detail.

### —Structure of Photoelectric Conversion Layer—

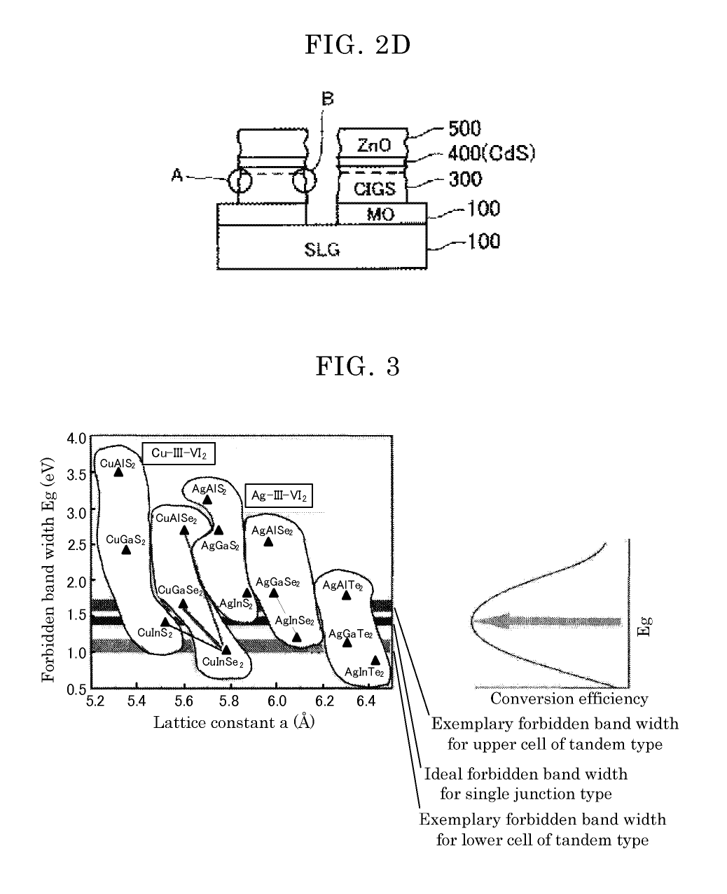

A thin-film solar battery which employs, as a light-absorbing layer, a CuInSe₂ thin film (CIS thin film) that is a chalcopyrite semiconductor thin film containing a group Ib element, a group IIIb element and a group VIb element, or a Cu(In,Ga)Se₂ thin film (CIGS thin film) formed by mixing the CuInSe₂ thin film with gallium to form a solid solution exhibits high energy conversion efficiency and has an advantage in that degradation of efficiency related to light irradiation, etc. can be reduced. FIGS. 2A to 2D are cross-sectional views of a device for explaining a general method for producing cells of a CIGS thin film solar battery.

First of all, as shown in FIG. 2A, a Mo (molybdenum) electrode layer 200 serving as a lower electrode on the positive side is formed on a substrate 100. Next, as shown in FIG. 2B, a light-absorbing layer 300 made of a CIGS thin film, which exhibits a p⁻ type by compositional control, is formed on the Mo electrode layer 200. Then, as shown in FIG. 2C, a buffer layer 400 made, for example, of CdS is formed on the light-absorbing layer 300, and a translucent electrode layer 500 made of ZnO (zinc oxide) as an upper electrode on the negative side, which exhibits an n⁺ type when doped with impurities, is formed on the buffer layer 400. Subsequently, as shown in FIG. 2D, the translucent electrode layer 500 made of ZnO, the Mo electrode layer 200 and the layers lying between these two layers are all together scribed using a mechanical scribe device. Thus, cells of the thin film solar battery are electrically divided (in other words, the cells are separated from one another). Substances which can be suitably formed into films in the present aspect are as follows.

(1) Substances each containing an element, a compound or an alloy which is in a liquid state at normal temperature or gets into a liquid state by heating
(2) Chalcogen compounds (compounds containing S, Se or Te)
II-VI compounds: ZnS, ZnSe, ZnTe, CdS, CdSe, CdTe and the like
I-III-VI₂ compounds: CuInSe₂, CuGaSe₂, Cu(In,Ga)Se₂, CuInS₂, CuGaSe₂, Cu(In,Ga)(S,Se)₂ and the like
I-III₃-VI₅ compounds: CuIn₃Se₅, CuGa₃Se₅, Cu(In,Ga)₃Se₅ and the like
   (3) Compounds with chalcopyrite structures and compounds with defect stannite structures
I-III-VI₂ compounds: CuInSe₂, CuGaSe₂, Cu(In,Ga)Se₂, CuInS₂, CuGaSe₂, Cu(In,Ga)(S,Se)₂ and the like
I-III₃-VI₅ compounds: CuIn₃Se₅, CuGa₃Se₅, Cu(In,Ga)₃Se₅ and the like

Regarding the foregoing, (In, Ga) and (S, Se) denote (In₁₋ₓGaₓ) and (S_{1-y}Se_{y}) (x=0 to 1, y=0 to 1), respectively.

The following shows a typical method for forming a CIGS layer. It should, however, be noted that the formation of a CIGS layer in the present invention is not limited thereto.

### (1) Multi-Source Simultaneous Vapor Deposition Method

Multi-source simultaneous vapor deposition methods are typified by the three-stage process developed by NREL (National Renewable Energy Laboratory) in USA, and the simultaneous vapor deposition method developed by EC Group. The three-stage process is described, for example, in Mat. Res. Soc. Symp. Proc., Vol. 426 (1996) p. 143 by J. R. Tuttle, J. S. Ward, A. Duda, T. A. Berens, M. A. Contreras, K. R. Ramanathan, A. L. Tennant, J. Keane, E. D. Cole, K. Emery and R. Noufi. The simultaneous vapor deposition method is described, for example, in Proc. 13th ECPVSEC (1995, Nice) 1451 by L. Stolt et al.

The three-stage process is a method of simultaneously vapor-depositing In, Ga and Se at a substrate temperature of 300° C. in high vacuum first, then simultaneously vapor-depositing Cu and Se at an increased substrate temperature of 500° C. to 560° C., and subsequently further simultaneously vapor-depositing In, Ga and Se, whereby a CIGS film with a graded band gap, whose forbidden band width varies, is obtained. The method developed by EC Group is a modified method whereby the bilayer method, in which Cu-excess CIGS is vapor-deposited at an early stage of vapor deposition and In-excess CIGS is vapor-deposited at a late stage thereof, developed by The Boeing Company can be applied to an in-line process. The bilayer method is described, for example, in IEEE Trans. Electron. Devices 37 (1990) 428 by W. E. Devaney, W. S. Chen, J. M. Stewart and R. A. Mickelsen.

The three-stage process and the simultaneous vapor deposition method by EC Group both have the following advantage: a Cu-excess CIGS film composition is employed in a film growth process, and liquid-phase sintering with a liquid-phase Cu₂₋ₓSe (x=0 to 1) which has undergone phase separation is utilized, so that particle diameters are enlarged and a CIGS film superior in crystallinity is thereby formed.

Nowadays, a variety of methods, in addition to these methods, are examined to improve the crystallinity of CIGS films. Note that such methods may be used as well.

### (a) Method Using Ionized Gallium

This is a method of passing evaporated gallium through a grid where there are thermoelectronic ions generated by means of a filament so as to make the gallium collide with the thermal electrons, and thereby ionizing the gallium. The ionized gallium is accelerated by extraction voltage and supplied to a substrate. Details of this method are described in phys. stat. sol. (a), Vol. 203 (2006) p. 2603 by H. Miyazaki, T. Miyake, Y. Chiba, A. Yamada and M. Konagai.

### (b) Method Using Cracked Selenium

This is a method in which evaporated selenium, generally in the form of a cluster, is thermally decomposed using a high-temperature heater so as to reduce molecules of the selenium cluster (68th Annual Meeting of The Japan Society of Applied Physics, Abstract of Lecture (autumn, 2007, Hokkaido Institute of Technology) 7P-L-6).

### (c) Method Using Radicalized Selenium

This is a method of using selenium radicals generated by means of a bulb tracking device (54th Annual Meeting of The Japan Society of Applied Physics, Abstract of Lecture (spring, 2007, Aoyama Gakuin University) 29P-ZW-10).

### (d) Method Using Photoexcitation Process

This is a method of irradiating the surface of a substrate with a KrF excimer laser (with a wavelength of 248 nm and a frequency of 100 Hz, for example) or a YAG laser (with a wavelength of 266 nm and a frequency of 10 Hz, for example) at the time of three-stage vapor deposition (54th Annual Meeting of The Japan Society of Applied Physics, Abstract of Lecture (spring, 2007, Aoyama Gakuin University) 29P-ZW-14).

### (2) Selenation Method

A selenation method, also called a two-stage process, is a method of forming a metal precursor film which is a laminated layer, for example Cu layer and In layer, or (Cu—Ga) layer and In layer, by sputtering, vapor deposition, electrodeposition or the like first, then heating this metal precursor film to between approximately 450° C. and approximately 550° C. in selenium vapor or selenated hydrogen so as to produce a selenium compound such as Cu(In₁₋ₓGaₓ)Se₂ by thermal diffusion. This method is specifically called a gas-phase selenation method. Apart from the gas-phase selenation method, there is a solid-phase selenation method in which solid-phase selenium is deposited over a metal precursor film and selenation is effected by solid-phase diffusion reaction using this solid-phase selenium as a selenium source. At present, the only successful method for mass production with area enlargement is a method of forming a metal precursor film by a sputtering method suitable for area enlargement and selenating this metal precursor film in selenated hydrogen.

However, this method present the following problems: there is approximately twofold volume expansion of the film at the time of selenation, so that internal distortion is caused; moreover, voids which are several micrometers or so in size are formed in the film produced, and these voids have adverse effects on the adhesion of the film to a substrate and solar battery properties, thereby limiting photoelectric conversion efficiency (NREL/SNL Photovoltaics Prog. Rev. Proc. 14th Conf. A Joint Meeting (1996) AIP Conf. Proc. 394 by B. M. Basol, V. K. Kapur, C. R. Leidholm, R. Roe, A. Halani and G. Norsworthy).

To avoid such dramatic volume expansion occurring at the time of selenation, there have been proposed a method of mixing selenium into a metal precursor film beforehand at a certain proportion (as described in “CuInSe₂-Based Solar Cells by Se-Vapor Selenization from Se-Containing Precursors” Solar Energy Materials and Solar Cells 35 (1994) 204-214 by T. Nakada, R. Ohnishi and A. kunioka); and use of a multilayered precursor film in which selenium is sandwiched between thin metal layers (for example, the structure of Cu layer/In layer/Se layer is repeatedly stacked) (as described in “Thin Films of CuInSe₂ Produced by Thermal Annealing of Multilayers with Ultra-Thin stacked Elemental Layers” Proc. of 10th European Photovoltaic Solar Energy Conference (1991) 887-890 by T. Nakada, K. Yuda and A. Kunioka). By the foregoing, the problem of volume expansion can be avoided to some extent.

However, all selenation methods including these methods have the following problem in common: a metal laminated film with a predetermined composition is used, and this metal laminated film is selenated, so that there is a very low degree of freedom in term of control of the film composition. For example, at present high-efficiency CIGS solar battery employs a CIGS thin film with a graded band gap, whose gallium concentration varies with respect to the film thickness direction; to produce this thin film by selenation, there is a method of depositing a Cu—Ga alloy film first, then depositing an indium film over the Cu—Ga alloy film, and allowing the gallium concentration to vary with respect to the film thickness direction by utilizing natural thermal diffusion when these films are selenated (refer to Tech. Digest 9th Photovoltaic Science and Engineering Conf. Miyazaki, 1996 (Intn. PVSEC-9, Tokyo, 1996) p. 149 by K. Kushiya, I. Sugiyama, M. Tachiyuki, T. Kase, Y. Nagoya, O. Okumura, M. Sato, O. Yamase and H. Takeshita).

### (3) Sputtering Method

The sputtering method is suitable for area enlargement, so that many procedures have hitherto been attempted as thin CuInSe₂ thin film forming procedures. For instance, there have been disclosed a method in which CuInSe₂ polycrystals are targeted, and a two-source sputtering method in which Cu₂Se and In₂Se₃ are targeted and a mixed gas of H₂Se and Ar is used as a sputter gas (refer to “CdS/CuInSe₂ Junctions Fabricated by DC Magnetron Sputtering of Cu₂Se and In₂Se₃” Proc. 18th IEEE Photovoltaic Specialists Conf. (1985) 1655-1658 by J. H. Ermer, R. B. Love, A. K. Khanna, S. C. Lewis and F. Cohen). Also, a three-source sputtering method, in which sputtering is performed using a Cu target, an In target and a Se or CuSe target in Ar gas, and the like have been reported (refer to “Polycrystalline CuInSe₂ Thin Films for Solar Cells by Three-Source Magnetron Sputtering” Jpn. J. Appl. Phys. 32 (1993) L1169-L1172 by T. Nakada, K. Migita and A. Kunioka; and “CuInSe₂ Films for Solar Cells by Multi-Source Sputtering of Cu, In and Se—Cu Binary Alloy” Proc. 4th Photovoltaic Science and Engineering Conf. (1989) 371-375 by T. Nakada, M. Nishioka and A. Kunioka).

### (4) Hybrid Sputtering Method

Assuming that a problem with the sputtering method is damage to the film surface caused by selenium negative ions or high-energy selenium particles, it must be possible to avoid this problem by subjecting only the selenium to thermal evaporation, not the sputtering. Nakada et al. formed a CIS thin film with fewer defects in accordance with a hybrid sputtering method, in which Cu and In are subjected to direct-current sputtering and selenium alone is subjected to vapor deposition, and thereby produced a CIS solar battery with a conversion efficiency of over 10% (refer to “Microstructural Characterization for Sputter-Deposited CuInSe₂ Films and Photovoltaic Devices” Jpn. Appl. Phys. 34 (1995) 4715-4721 by T. Nakada, K. Migita, S, Niki and A. Kunioka). Prior to the foregoing, Rockett et al. reported a hybrid sputtering method oriented to the use of selenium steam instead of H₂Se gas that is poisonous (Proc. 20th IEEE Photovoltaic Specialists Conf. (1988) 1505 by A. Rockett, T. C. Lommasson, L. C. Yang, H. Talieh, P. Campos and J. A. Thornton). Even earlier, there was reported a method of pe'rforming sputtering in selenium steam to compensate for a deficiency of selenium in a film (Jpn. J. Appl. Phys. 19 (Suppl. 19-3) (1980) 23 by S. Isomura, H. Kaneko, S. Tomioka, I. Nakatani and K. Masumoto).

### (5) Mechanochemical Process

Raw materials in the composition of CIGS are placed in a container of a planetary ball mill, and the raw materials are mixed together with mechanical energy so as to obtain CIGS powder. Thereafter, the CIGS powder is applied over a substrate by screen printing, which is followed by annealing, to thereby obtain a CIGS film (Phys. stat. sol. (a), Vol. 203 (2006) p 2593 by T. Wada, Y. Matsuo, S. Nomura, Y. Nakamura, A. Miyamura, Y. Chia, A. Yamada and M. Konagai).

### (6) Other Methods

Examples of other CIGS film forming methods include screen printing, close-spaced sublimation, MOCVD and spraying. A thin film composed of a group Ib element, a group IIIb element, a group VIb element and fine particles of compounds of these elements is formed over a substrate by screen printing, spraying, etc., and then the thin film is, for example, heat-treated, if necessary in an atmosphere of a group VIb element, so as to obtain crystals with a desired composition. For instance, a thin film is formed by applying fine oxide particles, then the thin film is heated in an atmosphere of selenated hydrogen. A thin film of an organic metal compound containing PVSEC-17 PL5-3 or a metal-group VIb element bond is formed on a substrate by spraying, printing, etc. and the thin film is thermally decomposed so as to obtain a desired thin inorganic film. When sulfur is used, examples of usable compounds include metal mercaptides, thioacid salts of metals, dithioacid salts of metals, thiocarbonate salts of metals, dithiocarbonate salts of metals, trithiocarbonate salts of metals, thiocarbamic acid salts of metals and dithiocarbamic acid salts of metals (refer to JP-A Nos. 09-74065 and 09-74213).

### —Value of Bang Gap and Control of Distribution—

As the light-absorbing layer of the solar battery, a semiconductor containing a combination of a group I element, a group III element and a group VI element can be favorably used. Well-known semiconductors containing combinations such as this are shown in FIG. 3. FIG. 3 is a drawing showing the relationship between lattice constants and band gaps regarding semiconductors each containing a group Ib element, a group IIIb element and a group VIb element. Cu(In₁₋ₓGaₓ)Se₂(CIGS) is mixed crystals of CuInSe₂ and CuGaSe₂. The forbidden band width can be controlled between 1.04 eV and 1.68 eV by changing the Ga concentration x. Other mixed crystals include Cu(In,Al)Se₂, Ag(In,Ga)Se₂, CuIn(S,Se)₂ and AgIn(S,Se)₂. By changing compositional ratios, a variety of forbidden band widths (band gaps) can be obtained. When photons with energy which is greater than the energy of a band gap enter a semiconductor, the amount of energy by which it is greater than that of the band gap results in heat loss. It is known from a theoretical calculation that, regarding the spectrum of sunlight and a band gap, the greatest conversion efficiency can be yielded when the band gap is in the approximate range of 1.4 eV to 1.5 eV. In order to enhance the conversion efficiency of a CIGS solar battery, the gallium concentration of Cu(InₓGa₁₋ₓ)S₂, the aluminum concentration of Cu(InₓAlₓ)S₂ or the sulfur concentration of CuInGa(S,Se), for example, is increased so as to enlarge the band gap; by doing so, a band gap for high conversion efficiency is obtained. In the case of Cu(InₓGa₁₋ₓ)S₂, the band gap may be adjusted to the range of 1 eV to 1.68 eV.

Also, it is possible to add a gradient to a band structure by changing the compositional ratio with respect to the film thickness direction. There are two types of band gaps that can be thought of: a single graded band gap in which the band gap is increased from the light incidence window side toward an electrode on the opposite side; and a double graded band gap in which the band gap is decreased from the light incidence window side toward a p-n junction and the band gap is increased past the p-n junction. Solar batteries employing such band structures are disclosed, for example, in “A new approach to high-efficiency solar cells by band gap grading in Cu(In,Ga)Se₂ chalcopyrite semiconductors, Solar Energy Materials & Solar Cells, Vol. 67, p. 145-150 (2001) by T. Dullweber”. In each case, due to the electric field generated on the inside by the gradient of the band structure, light-induced carriers are accelerated and easily reach an electrode, and the probability of combination of the carriers and a recombination center is decreased, thereby improving power generation efficiency (refer to International Publication No. WO/2004/090995).

### —Tandem Type—

When a plurality of semiconductors with different band gaps corresponding to ranges of a spectrum are used, it is possible to reduce heat loss caused by the discrepancy between photon energy and a band gap and improve power generation efficiency. A device in which such a plurality of photoelectric conversion layers are used in combination is called a tandem type. In the case of a two-layer tandem type, employment of a combination of a band gap of 1.1 eV and a band gap of 1.7 eV makes it possible to improve power generation efficiency.

—Components Other than Photoelectric Conversion Layer—

For n-type semiconductors which form junctions with compound semiconductors, II-VI compounds such as CdS, ZnO, ZnS and Zn(O, S, OH) can be used. These compounds are preferable in that junction interfaces with photoelectric conversion layers can be formed without causing carrier recombination (refer to JP-A No. 2002-343987).

### [Substrate]

Examples of the substrate include glass plates such as plates of soda-lime glass; films such as of polyimides, polyethylene naphthalate, polyether sulfones, polyethylene terephthalate and aramids; metal plates such as plates of stainless steel, titanium, aluminum and copper; and the laminated mica substrate mentioned in JP-A No. 2005-317728. The element substrate is preferably in the form of film or foil.

### [Back Electrode]

A metal such as molybdenum, chromium or tungsten can be used as the back electrode. These metal materials are preferable in that they do not easily mix with other layers even when heat treatment is carried out. Use of a molybdenum layer is preferable in the case where a photovoltaic layer including a semiconductor layer (light-absorbing layer) formed of a compound semiconductor is used. At the boundary surface between the light-absorbing layer (CIGS) and the back electrode, there exists a recombination center. Thus, when the connection area between the back electrode and the light-absorbing layer is larger than is necessary for electrical conductivity, there is a decrease in power generation efficiency. To reduce the connection area, use of an electrode layer with a structure in which insulating material and metal are disposed in the form of stripes is favorable (refer to JP-A No. 09-219530).

Examples of layer structures include superstrate-type structures and substrate-type structures. In the case where a photovoltaic layer including a semiconductor layer (light-absorbing layer) formed of a compound semiconductor is used, employment of a substrate-type structure is preferable in that high conversion efficiency can be obtained.

### [Buffer Layer]

For the buffer layer, CdS, ZnS, ZnS(O, OH), ZnMgO or the like can be used, for example. For instance, when the band gap of the light-absorbing layer is widened by increasing the gallium concentration of CIGS, its conduction band becomes far larger than the conduction band of ZnO; therefore, ZnMgO that has great conduction band energy is preferable for the buffer layer.

### [Transparent Conductive Layer]

It is preferred that the transparent conductive layer for use in the solar battery of the present invention be provided by applying the aqueous dispersion which contains the metal nanowires, after the buffer layer has been formed. Alternatively, the aqueous dispersion which contains the metal nanowires may be applied, after the buffer layer has been formed and then a ZnO layer has been formed.

The transparent conductive layer can be obtained by applying the aqueous dispersion over the substrate and drying the aqueous dispersion. The aqueous dispersion may be annealed by heating after its application. On this occasion, the heating temperature is preferably in the range of 50° C. to 300° C., more preferably 70° C. to 200° C.

The transparent conductive layer can be used for a transparent electrode of any solar battery. Also, it can be applied to a crystalline (single-crystalline, polycrystalline, etc.) silicon solar battery in which a collector electrode is generally not a transparent electrode. In the crystalline silicon solar battery, a silver-deposited electrical wire or a silver-pasted electrical wire is generally used as a collector electrode; application of the transparent conductive layer of the present invention to the crystalline silicon solar battery, makes it possible to yield high photoelectric conversion efficiency in this case as well.

The transparent conductive layer for use in the solar battery of the present invention has high transmittance with respect to light in the infrared wavelength region and has small sheet resistance. Therefore, the transparent conductive layer can be suitably used in a solar battery which absorbs light in the infrared wavelength region, for example an amorphous silicon solar battery with a tandem structure, or a compound semiconductor solar battery such as a copper/indium/selenium (so-called CIS) semiconductor solar battery, a copper/indium/gallium/selenium (so-called CIGS) semiconductor solar battery or a copper/indium/gallium/selenium/sulfur (so-called CIGSS) semiconductor solar battery.

### EXAMPLES

The following explains Examples of the present invention. It should, however, be noted that the scope of the present invention is not confined to these Examples.

In Examples below, the average diameter (average minor axis length) and average major axis length of metal nanowires, the diameter (minor axis length) variation coefficient of the metal nanowires, the appropriate wire formation rate, and the sharpness of cross-sectional corners of the metal nanowires were measured as follows.

### <Average Diameter (Average Minor Axis Length) and Average Major Axis Length of Metal Nanowires>

Three hundred metal nanowires were observed using a transmission electron microscope (TEM; JEM-2000FX, manufactured by JEOL Ltd.), and the average diameter (average minor axis length) and average major axis length of metal nanowires were calculated by averaging the diameters (minor axis lengths) and major axis lengths of these 300 metal nanowires.

### <Diameter (Minor Axis Length) Variation Coefficient of Metal Nanowires>

The diameter variation coefficient of the metal nanowires was worked out by observing 300 metal nanowires with the use of a transmission electron microscope (TEM; JEM-2000FX, manufactured by JEOL Ltd.), measuring the diameters (minor axis lengths) of these 300 metal nanowires, and calculating the standard deviation and average value of the diameters (minor axis lengths).

### <Appropriate Wire Formation Rate>

A silver nanowire aqueous dispersion liquid was filtered so as to separate silver nanowires from particles which were not the silver nanowires. Then the amount of silver remaining on filter paper and the amount of silver which had passed through the filter paper were measured using an ICP emission analyzer (ICPS-8000, manufactured by SHIMADZU CORPORATION) so as calculate the metal amount (% by mass) of metal nanowires (appropriate wires) which were 50 nm or less in diameter (minor axis length) and 5 μM or greater in major axis length contained in all metal particles.

The separation of the appropriate wires in calculating the appropriate wire formation rate was performed using a membrane filter (FALP 02500, pore diameter: 1.0 μm, manufactured by Millipore Corporation).

### <Sharpness of Cross-Sectional Corners of Metal Nanowires>

As for the cross-sectional shape of each metal nanowire, a metal nanowire aqueous dispersion liquid was applied over a base material, and a cross section of the base material coated with the dispersion liquid was observed using a transmission electron microscope (TEM; JEM-2000FX, manufactured by JEOL Ltd.). Three hundred metal nanowires were selected, and the cross-sectional outer circumference and the total length of the cross-sectional sides were measured regarding each of these 300 metal nanowires so as to calculate the sharpness, i.e. the proportion of the “cross-sectional outer circumference” to the total length of the “cross-sectional sides”. When the sharpness was 75% or less, the cross-sectional shape was defined as a cross-sectional shape with round corners.

### <SP Value of Solvent>

The SP value of a solvent was calculated in accordance with the Okitsu method (“Journal of the Adhesion Society of Japan”, 29(3) (1993), authored by Toshinao Okitsu). Specifically, the SP value was calculated using the following equation. Note that ΔF denotes the value mentioned in the journal.

SP value (δ)=ΣΔF(Molar attraction constants)/V(Molar volume)

In a case where a plurality of mixed solvents were used, the SP value (σ) and the hydrogen-bonding term (σh) of the SP value were calculated using the following equation.

$$σ or {σ}_{h} = \frac{{M}_{1} {V}_{1} {σ}_{1} + {M}_{2} {V}_{2} {σ}_{2} + {M}_{3} {V}_{3} {σ}_{3} + … {M}_{n} {V}_{n} {σ}_{n}}{{M}_{1} {V}_{1} + {M}_{2} {V}_{2} + {M}_{3} {V}_{3} + … {M}_{n} {V}_{n} σ}$$

In this equation, an denotes the SP value of each solvent or the hydrogen-bonding term of the SP value of each solvent, Mn denotes the mole fraction of each solvent in the mixed solvents, Vn denotes the molar volume of each solvent, and n denotes an integer of 2 or greater which shows the number of kinds of solvents used.

### <Water Content of Conductive Composition>

The water content of a conductive composition was the value (% by mass) obtained by measuring the water content of the conductive composition three times with a Karl Fischer moisture meter (MKC-610, manufactured by Kyoto Electronics Manufacturing Co., Ltd.), and averaging the obtained values.

### [Abbreviations in Synthesis Examples]

The meanings of the abbreviations used in Synthesis Examples below are as follows.
MAA: methacrylic acid
MMA: methyl methacrylate
CHMA: cyclohexyl methacrylate
St: styrene
GMA: glycidyl methacrylate
DCM: dicyclopentanyl methacrylate
BzMA: benzyl methacrylate
AIBN: azobisisobutyronitrile
PGMEA: propylene glycol monomethyl ether acetate
MFG: 1-methoxy-2-propanol
THF: tetrahydrofuran

### Synthesis Example 1

### Synthesis of Binder (A-1)

MAA (7.79 g) and BzMA (37.21 g) were used as monomer components constituting a copolymer, AIBN (0.5 g) was used as a radical polymerization initiator, and a PGMEA solution (solid content concentration: 45% by mass) of a binder (A-1) was obtained by subjecting these compounds to polymerization reaction in a solvent of PGMEA (55.00 g). The polymerization temperature was adjusted to the range of 60° C. or 100° C.

As a result of measuring its molecular weight by gel permeation chromatography (GPC), its polystyrene-equivalent weight average molecular weight (Mw) was 30,000, and the molecular weight distribution (Mw/Mn) was 2.21.

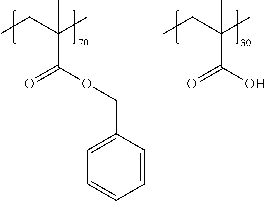

### Synthesis Example 2

### Synthesis of Binder (A-2)

In a reaction container, 7.48 g of MFG (manufactured by NIPPON NYUKAZAI CO., LTD.) was placed in advance, the temperature was increased to 90° C., and then a mixed solution containing MAA (14.65 g), MMA (0.54 g) and CHMA (17.55 g) as monomer components, AIBN (0.50 g) as a radical polymerization initiator, and MFG (55.2 g) was applied dropwise into the reaction container (90° C.) for 2 hours in a nitrogen gas atmosphere. After its dropwise application, the mixture was reacted for 4 hours so as to obtain an acrylic resin solution.

Subsequently, 0.15 g of hydroquinone monomethyl ether and 0.34 g of tetraethylammonium bromide were added to the obtained acrylic resin solution, then 12.26 g of GMA was applied dropwise for 2 hours. After its application, the mixture was reacted at 90° C. for 4 hours with a continuous blow of air, then PGMEA was added such that the solid content concentration became 45% by mass, and a solution (solid content concentration: 45% by mass) of a binder (A-2) was thus obtained.

As a result of measuring its molecular weight by gel permeation chromatography (GPC), its polystyrene-equivalent weight average molecular weight (Mw) was 31,300, and the molecular weight distribution (Mw/Mn) was 2.32.

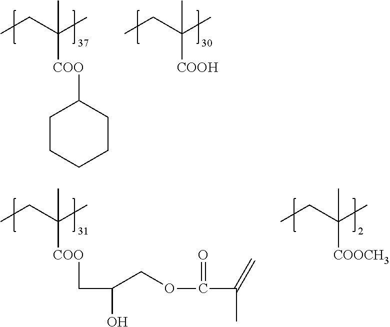

### Preparation Example 1

### Preparation of Silver Nanowire Aqueous Dispersion Liquid (1)

The following additive solutions A, G and H were prepared in advance.

### [Additive Solution A]

In 50 mL of purified water, 0.51 g of silver nitrate powder was dissolved. Thereafter, 1N ammonia water was added until the solution became transparent. Then purified water was added such that the total amount became 100 mL.

### [Additive Solution G]

In 140 mL of purified water, 0.5 g of glucose powder was dissolved so as to prepare an additive solution G.

[Additive Solution H]

In 27.5 mL of purified water, 0.5 g of HTAB (hexadecyltrimethylammonium bromide) powder was dissolved so as to prepare an additive solution H.

Next, a silver nanowire aqueous dispersion liquid was prepared in the following manner.

Into a three-necked flask, 410 mL of purified water was poured, then 82.5 mL of the additive solution H and 206 mL of the additive solution G were added at 20° C. with agitation, using a funnel (first stage). To the obtained solution, 206 mL of the additive solution A was added at a flow rate of 2.0 mL/min and an agitation rotational speed of 800 rpm (second stage). Ten minutes afterward, 82.5 mL of the additive solution H was added (third stage). Thereafter, the internal temperature was increased to 75° C. at a rate of 3° C./min. After that, the agitation rotational speed was lowered to 200 rpm, and heating was carried out for 5 hours.

The obtained aqueous dispersion solution was cooled, then the ultrafiltration module SIP1013 (molecular weight cut off: 6,000, manufactured by Asahi Kasei Corporation), a magnet pump and a stainless steel cup were connected by a silicone tube to constitute an ultrafiltration apparatus.

The silver nanowire aqueous dispersion liquid was poured into the stainless steel cup, then ultrafiltration was performed by operating the pump. When the amount of filtrate coming from the module stood at 50 mL, 950 mL of distilled water was poured into the stainless steel cup to carry out washing. The washing was repeated until the conductivity became equal to or lower than 50 μS/cm, then concentration was carried out, and a silver nanowire aqueous dispersion liquid (1) was thus obtained.

Regarding the silver nanowires obtained in Preparation Example 1, the average minor axis length, the average major axis length, the appropriate wire formation rate, the diameter (minor axis length) variation coefficient, and the sharpness of cross-sectional corners are shown in Table 1.

### Preparation Example 2

### Preparation of Silver Nanowire Aqueous Dispersion Liquid (2)

The same process as in Preparation Example 1 was carried out except that the initial temperature of the mixed solution at the first stage was changed from 20° C. to 40° C., and a silver nanowire aqueous dispersion liquid (2) according to Preparation Example 2 was thus produced.

Regarding the silver nanowires obtained in Preparation Example 2, the average minor axis length, the average major axis length, the appropriate wire formation rate, the diameter (minor axis length) variation coefficient, and the sharpness of cross-sectional corners are shown in Table 1.

### Preparation Example 3

### Preparation of Silver Nanowire Aqueous Dispersion Liquid (3)

The same process as in Preparation Example 1 was carried out except that the addition at the third stage took place 40 minutes after the addition at the second stage, and a silver nanowire aqueous dispersion liquid (3) according to Preparation Example 3 was thus produced.

Regarding the silver nanowires obtained in Preparation Example 3, the average minor axis length, the average major axis length, the appropriate wire formation rate, the diameter (minor axis length) variation coefficient, and the sharpness of cross-sectional corners are shown in Table 1.

### Preparation Example 4

### Preparation of Silver Nanowire Aqueous Dispersion Liquid (4)

Thirty milliliters of ethylene glycol was poured into a three-necked flask and heated to 160° C. Thereafter, 36 mM of polyvinylpyrrolidone (PVP, K-55), 3 μM of iron acetylacetonate, 18 mL of 60 μM of sodium chloride ethylene glycol solution and 18 mL of 24 mM of silver nitrate ethylene glycol solution were added at a rate of 1 mL/min. The mixed solution was heated at 160° C. for 60 minutes and then cooled to room temperature. The mixed solution was centrifuged with the addition of water, then refinement was carried out until the conductivity became equal to or lower than 50 μS/cm, and a silver nanowire aqueous dispersion was thus obtained.

Regarding the silver nanowires obtained in Preparation Example 4, the average minor axis length, the average major axis length, the appropriate wire formation rate, the diameter (minor axis length) variation coefficient, and the sharpness of cross-sectional corners are shown in Table 1.

The ultrafiltration module SIP1013 (molecular weight cut off: 6,000, manufactured by Asahi Kasei Corporation), a magnet pump and a stainless steel cup were connected by a silicone tube to constitute an ultrafiltration apparatus.

The silver nanowire aqueous dispersion liquid was poured into the stainless steel cup, then ultrafiltration was performed by operating the pump. When the amount of filtrate coming from the module stood at 50 mL, 950 mL of distilled water was poured into the stainless steel cup to carry out washing. The washing was repeated until the conductivity became equal to or lower than 50 μS/cm, then concentration was carried out, and a silver nanowire aqueous dispersion liquid (4) was thus obtained.

Regarding each of the silver nanowire aqueous dispersion liquids obtained in Preparation Examples 1 to 4, the average minor axis length, the average major axis length, the appropriate wire formation rate, the diameter (minor axis length) variation coefficient, and the sharpness of cross-sectional corners are shown in Table 1.

TABLE 1

| | | | Appropri- | | Sharpness |
|---|---|---|---|---|---|
| | Average | Average | ate wire | Diameter | of cross- |
| | minor axis | major axis | formation | variation | sectional |
| | length | length | rate (% by | coefficient | corners |
| | (nm) | (μm) | mass) | (%) | (%) |
| Preparation | 17.6 | 36.7 | 82.6 | 18.3 | 47.3 |
| Example 1 | | | | | |
| Preparation | 62.4 | 34.6 | 68.4 | 43.4 | 32.7 |
| Example 2 | | | | | |
| Preparation | 18.4 | 13.4 | 73.2 | 23.5 | 46.5 |
| Example 3 | | | | | |
| Preparation | 110.0 | 32.0 | 87.2 | 19.2 | 87.3 |
| Example 4 | | | | | |

### Positive Formulation

### Example 1

### Preparation of Conductive Composition (1)

To 100 parts by mass of the silver nanowire aqueous dispersion liquid (1) prepared in Preparation Example 1, 1 part by mass of polyvinylpyrrolidone (K-30, manufactured by TOKYO CHEMICAL INDUSTRY CO., LTD.) and 100 parts by mass of propylene glycol monomethyl ether acetate (PGMEA) were added. Subsequently, centrifugation was carried out, then supernatant water was removed by decantation, PGMEA was added, and redispersion was carried out. Then the above-mentioned process (composed of the centrifugation, the removal of supernatant water, the addition of PGMEA and the redispersion) was repeated three times, finally PGMEA was added, and a silver nanowire PGMEA dispersion liquid (1) was thus obtained. The amount of the PGMEA finally added was adjusted such that the silver content became 10% by mass.

Next, 4.19 parts by mass of the binder (A-1) (solid content: 40.0% by mass, PGMEA solution), 0.95 parts by mass of TAS-200 (esterification rate: 66%, manufactured by Toyo Gosei Co., Ltd.) represented by the structural formula below as a photosensitive compound, 0.80 parts by mass of EHPE-3150 (manufactured by DAICEL CHEMICAL INDUSTRIES, LTD.) as a cross-linking agent, and 19.06 parts by mass of PGMEA as a solvent were added to 7.5 parts by mass of the silver nanowire PGMEA dispersion liquid (1), then the mixture was agitated, and a conductive composition (1) was prepared such that the silver concentration was 1.0% by mass and the SP value of the solvent was 20.0 MPa^{1/2}. The water content of the conductive composition (1) obtained was 0.2% by mass. The SP value of the solvent was adjusted using ethyl lactate and isopropyl acetate.

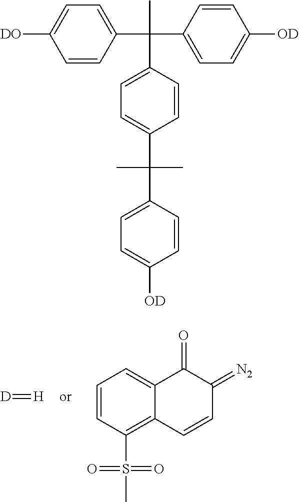

### Example 2

### Preparation of Conductive Composition (2)

The same process as in Example 1 was carried out except that the silver nanowire aqueous dispersion liquid (2) was used instead of the silver nanowire aqueous dispersion liquid (1), and a conductive composition (2) was thus prepared. The water content of the conductive composition (2) obtained was 0.2% by mass.

### Example 3

### Preparation of Conductive Composition (3)

The following were added to 15 parts by mass of the silver nanowire PGMEA dispersion liquid (1) produced as in Example 1: 3.72 parts by mass of the binder (A-2) (solid content: 45.0% by mass, MFG/PGMEA solution); 0.95 parts by mass of TAS-200 (esterification rate: 66%, manufactured by Toyo Gosei Co., Ltd.) represented by the above structural formula as a photosensitive compound; 0.80 parts by mass of EHPE-3150 (manufactured by DAICEL CHEMICAL INDUSTRIES, LTD.) as a cross-linking agent; and 19.53 parts by mass of PGMEA as a solvent. Then the mixture was agitated, and a conductive composition (3) was prepared such that the silver concentration was 1.0% by mass and the SP value of the solvent was 20.0 MPa^{1/2}. The water content of the conductive composition (3) obtained was 0.4% by mass. The SP value of the solvent was adjusted using ethyl lactate and isopropyl acetate.

### Example 4

### Preparation of Conductive Composition (4)

The same process as in Example 3 was carried out except that the silver nanowire aqueous dispersion liquid (2) prepared in Preparation Example 2 was used instead of the silver nanowire aqueous dispersion liquid (1), and a conductive composition (4) was thus prepared. The water content of the conductive composition (4) obtained was 0.3% by mass.

### Example 5

### Preparation of Conductive Composition (5)

The same process as in Example 1 was carried out except that the silver nanowire aqueous dispersion liquid (3) prepared in Preparation Example 3 was used instead of the silver nanowire aqueous dispersion liquid (1), and a conductive composition (5) was thus prepared. The water content of the conductive composition (5) obtained was 0.2% by mass.

### Example 6

### Preparation of Conductive Composition (6)

The same process as in Example 1 was carried out except that the silver nanowire aqueous dispersion liquid (4) prepared in Preparation Example 4 was used instead of the silver nanowire aqueous dispersion liquid (1), and a conductive composition (6) was thus prepared. The water content of the conductive composition (6) obtained was 1.1% by mass.

### Example 7

### Preparation of Conductive Composition (7)

The same process as in Example 1 was carried out except that when the conductive composition was prepared, the water content was adjusted to 15% by mass and the SP value of the solvent was adjusted to 22.0 MPa^{1/2}, and a conductive composition (7) was thus prepared.

### Example 8

### Preparation of Conductive Composition (8)

The same process as in Example 1 was carried out except that when the conductive composition was prepared, the water content was adjusted to 25% by mass and the SP value of the solvent was adjusted to 24.0 MPa^{1/2}, and a conductive composition (8) was thus prepared.

### Example 9

### Preparation of Conductive Composition (9)

The same process as in Example 1 was carried out except that the SP value of the solvent was adjusted to 17.5 MPa^{1/2}, and a conductive composition (9) was thus prepared. The water content of the conductive composition (9) obtained was 0.3% by mass.

### Example 10

### Preparation of Conductive Composition (10)

The same process as in Example 1 was carried out except that the SP value of the solvent was adjusted to 18.2 MPa^{1/2}, and a conductive composition (10) was thus prepared. The water content of the conductive composition (10) obtained was 0.3% by mass.

### Example 11

### Preparation of Conductive Composition (11)

The same process as in Example 1 was carried out except that the SP value of the solvent was adjusted to 28.0 MPa^{1/2}, and a conductive composition (11) was thus prepared. The water, content of the conductive composition (11) obtained was 0.4% by mass.

### Example 12

### Preparation of Conductive Composition (12)

The same process as in Example 1 was carried out except that when the conductive composition was prepared, the water content was adjusted to 35% by mass and the SP value of the solvent was adjusted to 27.5 MPa^{1/2}, and a conductive composition (12) was thus prepared.

### Example 13

### Preparation of Conductive Composition (13)

The same process as in Example 1 was carried out except that the SP value of the solvent was adjusted to 19.0 MPa^{1/2}, and a conductive composition (13) was thus prepared. The water content of the conductive composition (13) obtained was 0.3% by mass.

### Example 14

### Preparation of Conductive Composition (14)

The same process as in Example 1 was carried out except that the SP value of the solvent was adjusted to 27.0 MPa^{1/2}, and a conductive composition (14) was thus prepared. The water content of the conductive composition (14) obtained was 0.2% by mass.

### Example 15

### Preparation of Conductive Composition (15)

The same process as in Example 1 was carried out except that the SP value of the solvent was adjusted to 26.0 MPa^{1/2}, and a conductive composition (15) was thus prepared. The water content of the conductive composition (15) obtained was 0.4% by mass.

### Comparative Example 1

### Preparation of Conductive Composition (16)

The same process as in Example 1 was carried out except that when the conductive composition was prepared, the water content was adjusted to 28% by mass and the SP value of the solvent was adjusted to 30.3 MPa^{1/2}, and a conductive composition (16) was thus prepared.

### Negative Formulation

### Example 16

### Preparation of Conductive Composition (17)

To 100 parts by mass of the silver nanowire aqueous dispersion liquid (1) prepared in Preparation Example 1, 1 part by mass of polyvinylpyrrolidone (K-30, manufactured by TOKYO CHEMICAL INDUSTRY CO., LTD.) and 100 parts by mass of propylene glycol monomethyl ether acetate (PGMEA) were added. Subsequently, centrifugation was carried out, then supernatant water was removed by decantation, PGMEA was added, and redispersion was carried out. Then the above-mentioned process (composed of the centrifugation, the removal of supernatant water, the addition of PGMEA and the redispersion) was repeated three times, finally PGMEA was added, and a silver nanowire PGMEA dispersion liquid (1) was thus obtained. The amount of the PGMEA finally added was adjusted such that the silver content became 10% by mass.

Next, 3.80 parts by mass of the binder (A-1) (solid content: 40.0% by mass, PGMEA solution), 1.59 parts by mass of KAYARAD DPHA (manufactured by Nippon Kayaku Co., Ltd.) as a photosensitive compound, 0.159 parts by mass of IRGACURE 379 (manufactured by Ciba Specialty Chemicals plc.) as a photosensitive compound, 0.150 parts by mass of EHPE-3150 (manufactured by DAICEL CHEMICAL INDUSTRIES, LTD.) as a cross-linking agent, 0.002 parts by mass of MEGAFAC F781F (manufactured by DIC Corporation) as an agent for improving the state of a coated surface and 19.3 parts by mass of PGMEA as a solvent were added to 7.5 parts by mass of the silver nanowire PGMEA dispersion liquid (1), then the mixture was agitated, and a conductive composition (17) was prepared such that the silver concentration was 1.0% by mass and the SP value of the solvent was 20.0 MPa^{1/2}. The water content of the conductive composition (17) obtained was 0.2% by mass. The SP value of the solvent was adjusted using ethyl lactate and isopropyl acetate.

### Example 17

### Preparation of Conductive Composition (18)

The same process as in Example 16 was carried out except that the silver nanowire aqueous dispersion liquid (2) prepared in Preparation Example 2 was used instead of the silver nanowire aqueous dispersion liquid (1) prepared in Preparation Example 1, and a conductive composition (18) was thus prepared. The water content of the conductive composition (18) obtained was 0.3% by mass/(Example 18)

### Preparation of Conductive Composition (19)

To 100 parts by mass of the silver nanowire aqueous dispersion liquid (1) prepared in Preparation Example 1, 1 part by mass of polyvinylpyrrolidone (K-30, manufactured by TOKYO CHEMICAL INDUSTRY CO., LTD.) and 100 parts by mass of propylene glycol monomethyl ether acetate (PGMEA) were added. Subsequently, centrifugation was carried out, then supernatant water was removed by decantation, PGMEA was added, and redispersion was carried out. Then the above-mentioned process (composed of the centrifugation, the removal of supernatant water, the addition of PGMEA and the redispersion) was repeated three times, finally PGMEA was added, and a silver nanowire PGMEA dispersion liquid (1) was thus obtained. The amount of the PGMEA finally added was adjusted such that the silver content became 10% by mass.

Next, 3.38 parts by mass of the binder (A-2) (solid content: 45.0% by mass, MFG/PGMEA solution), 1.59 parts by mass of KAYARAD DPHA (manufactured by Nippon Kayaku Co., Ltd.) as a photosensitive compound, 0.159 parts by mass of IRGACURE 379 (manufactured by Ciba Specialty Chemicals plc.) as a photosensitive compound, 0.150 parts by mass of EHPE-3150 (manufactured by DAICEL CHEMICAL INDUSTRIES, LTD.) as a cross-linking agent, 0.002 parts by mass of MEGAFAC F781F (manufactured by DIC Corporation) as an agent for improving the state of a coated surface and 19.7 parts by mass of PGMEA as a solvent were added to 7.5 parts by mass of the silver nanowire PGMEA dispersion liquid (1), then the mixture was agitated, and a conductive composition (19) was prepared such that the silver concentration was 1.0% by mass and the SP value of the solvent was 20.0 MPa^{1/2}. The water content of the conductive composition (19) obtained was 0.2% by mass. The SP value of the solvent was adjusted using ethyl lactate and isopropyl acetate.

### Example 19

### Preparation of Conductive Composition (20)

The same process as in Example 18 was carried out except that the silver nanowire aqueous dispersion liquid (2) prepared in Preparation Example 2 was used instead of the silver nanowire aqueous dispersion liquid (1) prepared in Preparation Example 1, and a conductive composition (20) was thus prepared. The water content of the conductive composition (20) obtained was 0.3% by mass.

### Example 20

### Preparation of Conductive Composition (21)

The same process as in Example 16 was carried out except that the silver nanowire aqueous dispersion liquid (3) prepared in Preparation Example 3 was used instead of the silver nanowire aqueous dispersion liquid (1) prepared in Preparation Example 1, and a conductive composition (21) was thus prepared. The water content of the conductive composition (21) obtained was 0.3% by mass.

### Example 21

### Preparation of Conductive Composition (22)

The same process as in Example 16 was carried out, except that the silver nanowire aqueous dispersion liquid (4) prepared in Preparation Example 4 was used instead of the silver nanowire aqueous dispersion liquid (1) prepared in Preparation Example 1, and a conductive composition (22) was thus prepared. The water content of the conductive composition (22) obtained was 1.0% by mass.

### Example 22

### Preparation of Conductive Composition (23)

The same process as in Example 16 was carried out except that when the conductive composition was prepared, the water content was adjusted to 15% by mass and the SP value of the solvent was adjusted to 22.0 MPa^{1/2}, and a conductive composition (23) was thus prepared.

### Example 23

### Preparation of Conductive Composition (24)

The same process as in Example 16 was carried out except that when the conductive composition was prepared, the water content was adjusted to 25% by mass and the SP value of the solvent was adjusted to 24.0 MPa^{1/2}, and a conductive composition (24) was thus prepared.

### Example 24

### Preparation of Conductive Composition (25)

The same process as in Example 16 was carried out except that the SP value of the solvent was adjusted to 17.5 MPa^{1/2}, and a conductive composition (25) was thus prepared. The water content of the conductive composition (25) obtained was 0.2% by mass.

### Example 25

### Preparation of Conductive Composition (26)

The same process as in Example 16 was carried out except that the SP value of the solvent was adjusted to 18.2 MPa^{1/2}, and a conductive composition (26) was thus prepared. The water content of the conductive composition (26) obtained was 0.3% by mass.

### Example 26

### Preparation of Conductive Composition (27)

The same process as in Example 16 was carried out except that the SP value of the solvent was adjusted to 28.0 MPa^{1/2}, and a conductive composition (27) was thus prepared. The water content of the conductive composition (27) obtained was 0.5% by mass.

### Example 27

### Preparation of Conductive Composition (28)

The same process as in Example 16 was carried out except that the SP value of the solvent was adjusted to 19.0 MPa^{1/2}, and a conductive composition (28) was thus prepared. The water content of the conductive composition (28) obtained was 0.3% by mass.

### Example 28

### Preparation of Conductive Composition (29)

The same process as in Example 16 was carried out except that the SP value of the solvent was adjusted to 27.0 MPa^{1/2}, and a conductive composition (29) was thus prepared. The water content of the conductive composition (29) obtained was 0.3% by mass.

### Example 29

### Preparation of Conductive Composition (30)

The same process as in Example 16 was carried out except that the SP value of the solvent was adjusted to 26.0 MPa^{1/2}, and a conductive composition (30) was thus prepared. The water content of the conductive composition (30) obtained was 0.2% by mass.

### Example 30

### Preparation of Conductive Composition (31)

To 100 parts by mass of the silver nanowire aqueous dispersion liquid (1) prepared in Preparation Example 1, the following were added: 1 part by mass of polyvinylpyrrolidone (K-30, manufactured by TOKYO CHEMICAL INDUSTRY CO., LTD.), 50 parts by mass of ethanol and 50 parts by mass of 1-methoxy-2-propanol (MFG). Subsequently, centrifugation was carried out, then supernatant water was removed by decantation, and redispersion was carried out. Then the above-mentioned process (composed of the centrifugation, the removal of supernatant water and the redispersion) was repeated three times, finally MFG was added, and a silver nanowire MFG dispersion liquid (A) was thus obtained. The amount of the MFG finally added was adjusted such that the silver content became 10% by mass.

Next, 3.80 parts by mass of the binder (A-1) (solid content: 40.0% by mass, PGMEA solution), 1.59 parts by mass of KAYARAD DPHA (manufactured by Nippon Kayaku Co., Ltd.) as a photosensitive compound, 0.159 parts by mass of IRGACURE 379 (manufactured by Ciba Specialty Chemicals plc.) as a photosensitive compound, 0.150 parts by mass of EHPE-3150 (manufactured by DAICEL CHEMICAL INDUSTRIES, LTD.) as a cross-linking agent, 0.002 parts by mass of MEGAFAC F781F (manufactured by DIC Corporation) as an agent for improving the state of a coated surface and 19.3 parts by mass of MFG as a solvent were added to 7.5 parts by mass of the silver nanowire MFG dispersion liquid (A), then the mixture was agitated, and a conductive composition (31) was prepared such that the silver concentration was 1.0% by mass and the SP value of the solvent was 20.0 MPa^{1/2}. The water content of the conductive composition (31) obtained was 0.2% by mass. The SP value of the solvent was adjusted using ethyl lactate and isopropyl acetate.

### Example 31

### Preparation of Conductive Composition (32)

The same process as in Example 30 was carried out except that the EHPE-3150 as a cross-linking agent was not added, and a conductive composition (32) was thus prepared. The water content of the conductive composition (32) obtained was 0.3% by mass.

### Example 32

### Preparation of Conductive Composition (33)

The same process as in Example 30 was carried out except that the silver nanowire aqueous dispersion liquid (2) was used instead of the silver nanowire aqueous dispersion liquid (1), and a conductive composition (33) was thus prepared. The water content of the conductive composition (33) obtained was 0.3% by mass.

### Example 33

### Preparation of Conductive Composition (34)

The following were added to 15 parts by mass of the silver nanowire MFG dispersion liquid (A) prepared as in Example 30: 3.72 parts by mass of the binder (A-2) (solid content: 45.0% by mass, MFG/PGMEA solution); 0.95 parts by mass of TAS-200 (esterification rate: 66%, manufactured by Toyo Gosei Co., Ltd.) represented by the above structural formula as a photosensitive compound; and 19.53 parts by mass of MFG as a solvent. Then the mixture was agitated, and a conductive composition (34) was prepared such that the silver concentration was 1.0% by mass and the SP value of the solvent was 20.0 MPa^{1/2}. The water content of the conductive composition (34) obtained was 0.3% by mass. The SP value of the solvent was adjusted using ethyl lactate and isopropyl acetate.

### Example 34

### Preparation of Conductive Composition (35)

The same process as in Example 30 was carried out except that when the conductive composition was prepared, the water content was adjusted to 15% by mass and the SP value of the solvent was adjusted to 22.0 MPa^{1/2}, and a conductive composition (35) was thus prepared.

### Example 35

### Preparation of Conductive Composition (36)

The same process as in Example 30 was carried out except that when the conductive composition was prepared, the water content was adjusted to 25% by mass and the SP value of the solvent was adjusted to 24.0 MPa^{1/2}, and a conductive composition (36) was thus prepared.

### Example 36

### Preparation of Conductive Composition (37)

The same process as in Example 30 was carried out except that the SP value of the solvent was adjusted to 18.2 MPa^{1/2}, and a conductive composition (37) was thus prepared. The water content of the conductive composition (37) obtained was 0.3% by mass.

### Example 37

### Preparation of Conductive Composition (38)

The same process as in Example 30 was carried out except that the SP value of the solvent was adjusted to 28.0 MPa^{1/2}, and a conductive composition (38) was thus prepared. The water content of the conductive composition (38) obtained was 0.5% by mass.

### Example 38

### Preparation of Conductive Composition (39)

The same process as in Example 16 was carried out except that when the conductive composition was prepared, the water content was adjusted to 35% by mass and the SP value of the solvent was adjusted to 27.5 MPa^{1/2}, and a conductive composition (39) was thus prepared.

### Example 39

### Preparation of Conductive Composition (40)

The same process as in Example 30 was carried out except that the SP value of the solvent was adjusted to 19.0 MPa^{1/2}, and a conductive composition (40) was thus prepared. The water content of the conductive composition (40) obtained was 0.4% by mass.

### Example 40

### Preparation of Conductive Composition (41)

The same process as in Example 30 was carried out except that the SP value of the solvent was adjusted to 27.0 MPa^{1/2}, and a conductive composition (41) was thus prepared. The water content of the conductive composition (41) obtained was 0.2% by mass.

### Example 41

### Preparation of Conductive Composition (42)

The same process as in Example 30 was carried out except that the SP value of the solvent was adjusted to 26.0 MPa^{1/2}, and a conductive composition (42) was thus prepared. The water content of the conductive composition (42) obtained was 0.2% by mass.

### Comparative Example 2

### Preparation of Conductive Composition (43)

The same process as in Example 16 was carried out except that when the conductive composition was prepared, the water content was adjusted to 28% by mass and the SP value of the solvent was adjusted to 30.3 MPa^{1/2}, and a conductive composition (43) was thus prepared.

### Example 42

### Preparation of Conductive Composition (44)

The same process as in Example 30 was carried out except that when the conductive composition was prepared, the water content was adjusted to 35% by mass and the SP value of the solvent was adjusted to 27.5 MPa^{1/2}, and a conductive composition (44) was thus prepared.

### Comparative Example 3

### Preparation of Conductive Composition (45)

The same process as in Example 30 was carried out except that when the conductive composition was prepared, the water content was adjusted to 28% by mass and the SP value of the solvent was adjusted to 30.3 MPa^{1/2}, and a conductive composition (45) was thus prepared.

### Comparative Example 4

### Preparation of Silver Nanowire Aqueous Dispersion Liquid (Comparison 1)

To 100 parts by mass of the silver nanowire aqueous dispersion liquid (1) prepared in Preparation Example 1, 1 part by mass of polyvinylpyrrolidone (K-30, manufactured by TOKYO CHEMICAL INDUSTRY CO., LTD.) and 100 parts by mass of water were added. Subsequently, centrifugation was carried out, then supernatant water was removed by decantation, water was added, and redispersion was carried out. Then the above-mentioned process (composed of the centrifugation, the removal of supernatant water, the addition of water and the redispersion) was repeated three times, finally water was added, and a silver nanowire aqueous dispersion liquid (Comparison 1) was thus obtained. The amount of the water finally added was adjusted such that the silver content became 10% by mass.

### Preparation of Conductive Composition (46)

Next, 2.0 parts by mass of the binder (A-1), 7.5 parts by mass of 2-ethylhexyl acrylate as a photosensitive compound, 2.0 parts by mass of trimethylol triacrylate phosphate, 0.4 parts by mass of CIBA IRGACURE 754 (manufactured by Ciba Specialty Chemicals plc.) as a photosensitive compound, 0.1 parts by mass of GE SILQUEST A1100 (manufactured by GE Toshiba Silicones Co., Ltd.) as an adhesion promoter, 0.01 parts by mass of CIBA IRGANOX 101 OFF (manufactured by Ciba-Geigy Ltd.) as an antioxidant and 2.5 parts by mass of methyl ethyl ketone were added, and a conductive composition (46) which did not include silver nanowires was thus prepared.

Next, ingredients and production methods concerning the conductive compositions of Examples 1 to 42 and Comparative Examples 1 to 4 are shown together in Tables 2-1 to 2-3.

TABLE 2-1

| | Positive formulation | | | | | |
|---|---|---|---|---|---|---|
| | Silver | | | | | |
| | nanowire | | | Water | | |
| | aqueous | | | content | Cross- | Number of |
| | dispersion | | SP value | (% by | linking | appli- |
| | liquid | Binder | (MPa^{1/2}) | mass) | agent | cations |
| Ex. 1 | (1) | A-1 | 20.0 | 0.2 | Used | One |
| Ex. 2 | (2) | A-1 | 20.0 | 0.2 | Used | One |
| Ex. 3 | (1) | A-2 | 20.0 | 0.4 | Used | One |
| Ex. 4 | (2) | A-2 | 20.0 | 0.3 | Used | One |
| Ex. 5 | (3) | A-1 | 20.0 | 0.2 | Used | One |
| Ex. 6 | (4) | A-1 | 20.0 | 1.1 | Used | One |
| Ex. 7 | (1) | A-1 | 22.0 | 15 | Used | One |
| Ex. 8 | (1) | A-1 | 24.0 | 25 | Used | One |
| Ex. 9 | (1) | A-1 | 17.5 | 0.3 | Used | One |
| Ex. 10 | (1) | A-1 | 18.2 | 0.3 | Used | One |
| Ex. 11 | (1) | A-1 | 28.0 | 0.4 | Used | One |
| Ex. 12 | (1) | A-1 | 27.5 | 35 | Used | One |
| Ex. 13 | (1) | A-1 | 19.0 | 0.2 | Used | One |
| Ex. 14 | (1) | A-1 | 27.0 | 0.2 | Used | One |
| Ex. 15 | (1) | A-1 | 26.0 | 0.2 | Used | One |
| Comp. | (1) | A-1 | 30.3 | 28 | Used | One |
| Ex. 1 | | | | | | |

TABLE 2-2

| | Negative formulation | | | | | | |
|---|---|---|---|---|---|---|---|
| | Silver | Silver | | | | | |
| | nanowire | nanowire | | | Water | | |
| | aqueous | redis- | | | content | Cross- | Number of |
| | dispersion | persion | | SP value | (% by | linking | appli- |
| | liquid | solvent | Binder | (MPa^{1/2}) | mass) | agent | cations |
| Ex. 16 | (1) | PGMEA | A-1 | 20.0 | 0.2 | Used | One |
| Ex. 17 | (2) | PGMEA | A-1 | 20.0 | 0.3 | Used | One |
| Ex. 18 | (1) | PGMEA | A-2 | 20.0 | 0.2 | Used | One |
| Ex. 19 | (2) | PGMEA | A-2 | 20.0 | 0.3 | Used | One |
| Ex. 20 | (3) | PGMEA | A-1 | 20.0 | 0.3 | Used | One |
| Ex. 21 | (4) | PGMEA | A-1 | 20.0 | 1.0 | Used | One |
| Ex. 22 | (1) | PGMEA | A-1 | 22.0 | 15 | Used | One |
| Ex. 23 | (1) | PGMEA | A-1 | 24.0 | 25 | Used | One |
| Ex. 24 | (1) | PGMEA | A-1 | 17.5 | 0.2 | Used | One |
| Ex. 25 | (1) | PGMEA | A-1 | 18.2 | 0.3 | Used | One |
| Ex. 26 | (1) | PGMEA | A-1 | 28.0 | 0.5 | Used | One |
| Ex. 27 | (1) | PGMEA | A-1 | 19.0 | 0.3 | Used | One |
| Ex. 28 | (1) | PGMEA | A-1 | 27.0 | 0.3 | Used | One |
| Ex. 29 | (1) | PGMEA | A-1 | 26.0 | 0.2 | Used | One |
| Ex. 30 | (1) | MFG | A-1 | 20.0 | 0.2 | Used | One |
| Ex. 31 | (1) | MFG | A-1 | 20.0 | 0.3 | Not | One |
| | | | | | | used | |
| Ex. 32 | (2) | MFG | A-1 | 20.0 | 0.3 | Not | One |
| | | | | | | used | |
| Ex. 33 | (1) | MFG | A-2 | 20.0 | 0.3 | Not | One |
| | | | | | | used | |
| Ex. 34 | (1) | MFG | A-1 | 22.0 | 15 | Not | One |
| | | | | | | used | |
| Ex. 35 | (1) | MFG | A-1 | 24.0 | 25 | Not | One |
| | | | | | | used | |
| Ex. 36 | (1) | MFG | A-1 | 18.2 | 0.3 | Not | One |
| | | | | | | used | |
| Ex. 37 | (1) | MFG | A-1 | 28.0 | 0.5 | Not | One |
| | | | | | | used | |
| Ex. 38 | (1) | PGMEA | A-1 | 27.5 | 35 | Used | One |
| Ex. 39 | (1) | MFG | A-1 | 19.0 | 0.4 | Used | One |
| Ex. 40 | (1) | MFG | A-1 | 27.0 | 0.2 | Used | One |
| Ex. 41 | (1) | MFG | A-1 | 26.0 | 0.2 | Used | One |
| Comp. | (1) | PGMEA | A-1 | 30.3 | 28 | Used | One |
| Ex. 2 | | | | | | | |
| Ex. 42 | (1) | MFG | A-1 | 27.5 | 35 | Used | One |
| Comp. | (1) | MFG | A-1 | 30.3 | 28 | Not | One |
| Ex. 3 | | | | | | used | |

TABLE 2-3

| | Silver | | | | | |
|---|---|---|---|---|---|---|
| | nanowire | | | Water | | |
| | aqueous | | | content | Cross- | Number of |
| Comparative | dispersion | | SP value | (% by | linking | appli- |
| Example 4 | liquid | Binder | (MPa^{1/2}) | mass) | agent | cations |
| Silver nanowire | (1) | Not | 43.3 | 100 | Not | Two |
| aqueous dispersion | | used | | | used | |
| liquid (Comparison 1) | | | | | | |
| Conductive | Not | A-1 | 18.8 | 0 | Not | |
| composition (46) | used | | | | used | |

Next, patterned transparent conductive films including the conductive compositions of Examples 1 to 42 and Comparative, Examples 1 to 4 respectively were produced in the following manner, and properties of the patterned transparent conductive films were evaluated as described below. The results are shown in Tables 3-1 and 3-2.

### <Production of Patterned Transparent Conductive Films Concerning Examples 1 to 42 and Comparative Examples 1 to 3>

Each of the conductive compositions of Examples 1 to 42 and Comparative Examples 1 to 3 was applied over a glass substrate by slit coating and then prebaked by being dried for 2 minutes on a hotplate set at 90° C. This composition-coated glass substrate, with a mask placed thereon, was exposed to high-pressure mercury vapor lamp i-rays (with a wavelength of 365 nm) at an intensity of 100 mJ/cm² (irradiance of 20 mW/cm²). The exposed composition-coated glass substrate was subjected to shower development for 30 seconds, using a developing solution prepared by dissolving 5 g of sodium hydrogen carbonate and 2.5 g of sodium carbonate in 5,000 g of purified water. The shower pressure was 0.04 Mpa, and the length of time spent until a stripe pattern appeared was 15 seconds. Subsequently, rinsing with a shower of purified water was carried out, then post-baking was carried out at 200° C. for 10 minutes, and patterned transparent conductive films of Examples 1 to 42 and Comparative Examples 1 to 3 were thus produced.

### <Production of Patterned Transparent Conductive Film Concerning Comparative Example 4>

A patterned transparent conductive film was produced in the same manner as in Example 1 except that the silver nanowire aqueous dispersion liquid mentioned in Comparative Example 4 was applied over the glass substrate and then prebaked by being dried for 2 minutes on the hotplate set at 90° C. and subsequently the conductive composition mentioned in Comparative Example 4 was applied and then prebaked by being dried for 2 minutes on the hotplate set at 90° C.

### <Conductivity (Surface Resistance)>

The surface resistance of each patterned transparent conductive film, which had undergone the post-baking, was measured using LORESTA-GP MCP-T600 (manufactured by Mitsubishi Chemical Corporation).

### <Resolution>

The composition-coated substrate of each patterned transparent conductive film, which had undergone the post-baking, was observed at a magnification of 400 times, using an optical microscope, to examine the size (mask size) of sites where the glass was exposed at the bottom of a hole pattern. A case where the solubility was poor and the hole pattern was not resolved was judged to be “unfavorable”.

### <Transparency (Total Light Transmittance)>

The total light transmittance (%) of each patterned transparent conductive film obtained and the total light transmittance before the application of the transparent conductive film were measured using HAZE-GARD PLUS (manufactured by Gardner). The ratio between the former and the latter was defined as the transmittance of the transparent conductive film.

### <Solvent Resistance>

The composition-coated substrate of each patterned transparent conductive film obtained was immersed for 3 minutes, 5 minutes, 7 minutes and 10 minutes in N-methyl-2-pyrrolidone whose temperature was 100° C., and the size (mask size) of sites where the glass was exposed was examined. The solvent resistance was evaluated in accordance with the following criteria.

### [Evaluation Criteria]

A case where the solvent resistance was poor and the hole pattern was disturbed in the 3 minutes was judged to be “1”. A case where the hole pattern was disturbed in the 5 minutes was judged to be “2”. A case where the hole pattern was disturbed in the 7 minutes was judged to be “3”. A case where the hole pattern was disturbed in the 10 minutes was judged to be “4”. And a case where the hole pattern was not disturbed in the 10 minutes was judged to be “5”.

### <Alkali Resistance>

The composition-coated substrate of each patterned transparent conductive film obtained was immersed for 5 minutes, 10 minutes, 15 minutes and 20 minutes in a 5% potassium hydroxide aqueous solution whose temperature was 60° C., and the size (mask size) of sites where the glass was exposed was examined. The alkali Resistance was evaluated in accordance with the following criteria.

### [Evaluation Criteria]

A case where the alkali resistance was poor and the hole pattern was disturbed in the 5 minutes was judged to be “1”. A case where the hole pattern was disturbed in the 10 minutes was judged to be “2”. A case where the hole pattern was disturbed in the 15 minutes was judged to be “3”. A case where the hole pattern was disturbed in the 20 minutes was judged to be “4”. And a case where the hole pattern was not disturbed in the 20 minutes was judged to be “5”.

TABLE 3-1

| | Conductivity | | Transpar- | Solvent | Alkali |
|---|---|---|---|---|---|
| | (Ω/sq.) | Resolution | ency (%) | resistance | resistance |
| Ex. 1 | 11 | Favorable | 91 | 5 | 5 |
| Ex. 2 | 13 | Favorable | 90 | 4 | 5 |
| Ex. 3 | 12 | Favorable | 92 | 5 | 5 |
| Ex. 4 | 19 | Favorable | 90 | 5 | 5 |
| Ex. 5 | 16 | Favorable | 89 | 5 | 4 |
| Ex. 6 | 18 | Favorable | 87 | 4 | 5 |
| Ex. 7 | 18 | Favorable | 84 | 5 | 5 |
| Ex. 8 | 20 | Favorable | 86 | 5 | 4 |
| Ex. 9 | 13 | Favorable | 92 | 3 | 5 |
| Ex. 10 | 15 | Favorable | 93 | 3 | 5 |
| Ex. 11 | 20 | Favorable | 86 | 5 | 3 |
| Ex. 12 | 160 | Favorable | 90 | 4 | 2 |
| Ex. 13 | 20 | Favorable | 88 | 4 | 5 |
| Ex. 14 | 19 | Favorable | 89 | 5 | 4 |
| Ex. 15 | 25 | Favorable | 90 | 5 | 4 |
| Comp. | 17 | Favorable | 92 | 5 | 2 |
| Ex. 1 | | | | | |

TABLE 3-2

| | Conductivity | | Transpar- | Solvent | Alkali |
|---|---|---|---|---|---|
| | (Ω/sq.) | Resolution | ency (%) | resistance | resistance |
| Ex. 16 | 12 | Favorable | 90 | 5 | 5 |
| Ex. 17 | 15 | Favorable | 92 | 4 | 5 |
| Ex. 18 | 14 | Favorable | 93 | 5 | 4 |
| Ex. 19 | 20 | Favorable | 91 | 4 | 5 |
| Ex. 20 | 15 | Favorable | 91 | 5 | 5 |
| Ex. 21 | 17 | Favorable | 88 | 4 | 5 |
| Ex. 22 | 19 | Favorable | 85 | 5 | 4 |
| Ex. 23 | 19 | Favorable | 85 | 5 | 5 |
| Ex. 24 | 13 | Favorable | 92 | 3 | 5 |
| Ex. 25 | 14 | Favorable | 91 | 3 | 5 |
| Ex. 26 | 17 | Favorable | 88 | 5 | 3 |
| Ex. 27 | 20 | Favorable | 86 | 4 | 5 |
| Ex. 28 | 26 | Favorable | 90 | 5 | 4 |
| Ex. 29 | 24 | Favorable | 88 | 5 | 4 |
| Ex. 30 | 10 | Favorable | 93 | 5 | 5 |
| Ex. 31 | 17 | Favorable | 87 | 5 | 4 |
| Ex. 32 | 28 | Favorable | 88 | 4 | 5 |
| Ex. 33 | 25 | Favorable | 90 | 4 | 4 |
| Ex. 34 | 26 | Favorable | 83 | 5 | 4 |
| Ex. 35 | 25 | Favorable | 82 | 3 | 4 |
| Ex. 36 | 18 | Favorable | 91 | 3 | 4 |
| Ex. 37 | 20 | Favorable | 86 | 5 | 3 |
| Ex. 38 | 180 | Favorable | 91 | 5 | 2 |
| Ex. 39 | 30 | Favorable | 92 | 4 | 5 |
| Ex. 40 | 26 | Favorable | 88 | 5 | 4 |
| Ex. 41 | 29 | Favorable | 90 | 5 | 4 |
| Comp. | 18 | Favorable | 93 | 5 | 2 |
| Ex. 2 | | | | | |
| Ex. 42 | 170 | Favorable | 92 | 5 | 2 |
| Comp. | 15 | Favorable | 93 | 5 | 2 |
| Ex. 3 | | | | | |
| Comp. | 240 | Unfavorable | 78 | 1 | 1 |
| Ex. 4 | | | | | |

### Example 43 and Comparative Example 5

### Production of Display Element

A bottom-gate TFT was formed over a glass substrate, and an insulating film made of Si₃N₄ was formed in such a manner as to cover this TFT. Next, contact holes were formed in this insulating film, then wiring (1.0 μm in height) to be connected to the TFT via these contact holes was formed over the insulating film.

Further, to reduce the surface unevenness caused by the formation of the wiring, a flattening layer was formed over the insulating film in such a manner as to cover the uneven portions, and contact holes were formed, thereby obtaining a flat film A.

Next, the conductive composition (1) of Example 1 was applied over the flat film A by slit coating and then prebaking (90° C., 2 minutes) was carried out on a hotplate. Thereafter, the composition-coated film A, with a mask placed thereon, was irradiated with i-rays (with a wavelength of 365 nm) at an intensity of 100 mJ/cm² (irradiance of 20 mW/cm²) using a high-pressure mercury vapor lamp, then the exposed portions were removed by development using an alkali developing solution (TMAH aqueous solution, 0.4%), which was followed by heat treatment at 220° C. for 1 hour, and a transparent conductive film was thus produced. When operation of the TFT was examined, it was confirmed that the operation was favorable (Example 43).

As Comparative Example 5, an ITO patterned conductive film was formed over the flat film A. Operation of the TFT was similarly examined; in comparison with the case where the conductive composition (1) of Example 1 was used, the transmittance was poor and unevenness of interference in a diagonal direction was confirmed, so that the display element of Comparative Example 5 was judged to be problematic in practical use.

### Example 44

### Production of Display Element

The flat film A was produced as in Example 43, the conductive composition (17) of Example 16 was applied over the flat film A by slit coating and then prebaking (90° C., 2 minutes) was carried out on a hotplate. Thereafter, the composition-coated film A, with a mask placed thereon, was irradiated with i-rays (with a wavelength of 365 nm) at an intensity of 100 mJ/cm² (irradiance of 20 mW/cm²) using a high-pressure mercury vapor lamp, then the unexposed portions were removed by development using a 1.0% developing solution (diluted solution composed of 1 part by mass of the potassium hydroxide developing solution CDK-1, manufactured by FUJIFILM Electronic Materials Co., Ltd., and 99 parts by mass of purified water; 25° C.) of the potassium hydroxide developing solution CDK-1, which was followed by heat treatment at 220° C. for 1 hour, and a transparent conductive film was thus produced. When operation of the TFT was examined, it was confirmed that the operation was favorable.

### Comparative Example 6 and Example 45

### Production of Integrated Solar Battery

### —Production of Amorphous Solar Battery (Superstrate Type)—

A fluorine-doped tin oxide layer (transparent conductive film) having a thickness of 700 nm was formed over a glass substrate by MOCVD. Over this layer, a p-type amorphous silicon film having a thickness of approximately 15 nm, an i-type amorphous silicon film having a thickness of approximately 350 nm and an n-type amorphous silicon film having a thickness of approximately 30 nm were formed by plasma CVD, a gallium-doped zinc oxide layer having a thickness of 20 nm and a silver layer having a thickness of 200 nm were formed as a back reflective electrode, and a photoelectric conversion element 101 was thus produced (Comparative Example 6).

The same process as in the production of the photoelectric conversion element 101 was carried out except that, instead of the fluorine-doped tin oxide, the conductive composition (1) of Example 1 was applied as a transparent electrode over the glass substrate in such a manner as to allow its silver-equivalent amount to became 0.1 g/m², and that heating was carried out at 150° C. for 10 minutes. A photoelectric conversion element 102 (Example 45) was thus produced.

### Comparative Example 7 and Example 46

### Production of CIGS Solar Battery

### Substrate Type

Over a soda-lime glass substrate, a film of a molybdenum electrode having a thickness of approximately 500 nm was formed by direct-current magnetron sputtering, a Cu(In_{0.6}Ga_{0.4})Se₂ thin film having a thickness of approximately 2.5 μm made of a chalcopyrite semiconductor material was formed by vacuum vapor deposition, a cadmium sulfide thin film having a thickness of approximately 50 nm was formed by a solution deposition method, and a zinc oxide thin film having a thickness of approximately 50 nm was formed by MOCVD. Then, over these films, a boron-doped zinc oxide thin film (transparent conductive layer) having a thickness of approximately 100 nm was formed by direct-current magnetron sputtering, and a photoelectric conversion element 201 (Comparative Example 7) was thus produced.

The same process as in the production of the photoelectric conversion element 201 was carried out except that, instead of the boron-doped zinc oxide, the conductive composition (1) of Example 1 was used as a transparent electrode, and a photoelectric conversion element 202 was thus produced. Specifically, a cadmium sulfide thin film was formed, then the conductive composition (1) of Example 1 was applied over the cadmium sulfide thin film such that its silver-equivalent amount became 0.1 g/m². After its application, heating was carried out at 150° C. for 10 minutes, and the photoelectric conversion element 202 (Example 46) was thus produced.

Next, the conversion efficiency of each of the solar batteries produced was evaluated in the following manner. The results are shown in Table 4.

### <Evaluation of Solar Battery Property (Conversion Efficiency)>

Regarding each solar battery, the solar battery property (conversion efficiency) was measured by applying simulated sunlight (AM (air mass): 1.5, irradiance: 100 mW/cm²).

TABLE 4

| | | Transparent | Conversion |
|---|---|---|---|
| | | conductive | efficiency |
| | Sample | layer | (%) |
| Comparative | 101 | Fluorine-doped | 6 |
| Example 6 | | tin oxide | |
| Example 45 | 102 | Example 1 | 9 |
| Comparative | 201 | Zinc oxide | 7 |
| Example 7 | | | |
| Example 46 | 202 | Example 1 | 9 |

The results of Table 4 demonstrate that the use of the conductive composition of the present invention in the transparent conductive layers makes it possible to yield high conversion efficiency in both of the integrated solar battery systems.

### INDUSTRIAL APPLICABILITY

Since a conductive composition of the present invention is capable of securing both transparency and conductivity even after patterning by development, it can, for example, be suitably used for producing a patterned transparent conductive film, a display element, an integrated solar battery, etc.

### REFERENCE SIGNS LIST

200 Mo electrode layer
300 Light-absorbing layer
400 Buffer layer
500 Translucent electrode layer

1. A conductive composition comprising:
a binder;
a photosensitive compound;
metal nanowires; and
a solvent,
wherein the solvent has a solubility parameter value of 30 MPa^{1/2} or less.

2. The conductive composition according to claim 1, further comprising a cross-linking agent.

3. The conductive composition according to claim 1, wherein the solvent has a solubility parameter value of 18 MPa^{1/2} to 28 MPa^{1/2}.

4. The conductive composition according to claim 1, wherein the solvent has a solubility parameter value of 19 MPa^{1/2} to 27 MPa^{1/2}.

5. The conductive composition according to claim 1, having a water content of 30% by mass or less.

6. The conductive composition according to claim 1, wherein the solvent contains at least one selected from the group consisting of propylene glycol monomethyl ether acetate, ethyl lactate, isopropyl acetate and 1-methoxy-2-propanol.

7. The conductive composition according to claim 2, wherein the cross-linking agent is one of an epoxy resin and an oxetane resin.

8. The conductive composition according to claim 1, wherein the metal nanowires have an average minor axis length of 200 nm or less and an average major axis length of 1 μm or greater.

9. The conductive composition according to claim 1, wherein the metal amount of metal nanowires which are 50 nm or less in minor axis length and 5 μm or greater in major axis length occupies 50% by mass or more of the metal amount of all metal particles contained in the conductive composition.

10. The conductive composition according to claim 1, wherein the metal nanowires have a minor axis length variation coefficient of 40% or less.

11. The conductive composition according to claim 1, wherein the metal nanowires have round corners as seen in cross section.

12. The conductive composition according to claim 1, wherein the metal nanowires contain silver.

13. A pattern forming method comprising:
applying a conductive composition over a base material and drying the conductive composition so as to form a conductive layer; and
exposing and developing the conductive layer,
wherein the conductive composition contains:
a binder;
a photosensitive compound;
metal nanowires; and
a solvent,
wherein the solvent has a solubility parameter value of 30 MPa^{1/2} or less.

14. A transparent conductive film comprising:
a conductive composition, the conductive composition comprising:
a binder;
a photosensitive compound;
metal nanowires; and
a solvent,
wherein the solvent has a solubility parameter value of 30 MPa^{1/2} or less.

15.-16. (canceled)
